(19) United States
(12) Patent Application Publication
(10) Pub. No.: US 2026/0211271 A1
(43) Pub. Date: Jul. 23, 2026

(54) Heterogenous Photonic Integration

(71) Applicants: Massachusetts Institute of Technology, Cambridge, MA (US); Nanyang Technological University, Singapore (SG)

(72) Inventors: Luigi Ranno, Cambridge, MA (US); Jia Xu Brian Sia, Boston, MA (US); Juejun Hu, Newton, MA (US); Caroline Ross, Arlington, MA (US); Steven Vitale, Cambridge, MA (US); Tian GU, Acton, MA (US); Qingyang Du, Cambridge, MA (US); Cosmin-Constantin Popescu, Cambridge, MA (US); Kensuke Hayashi, Cambridge, MA (US); Khoi Phuong Dao, Cambridge, MA (US)

(73) Assignees: Massachusetts Institute of Technology, Cambridge, MA (US); Nanyang Technological University, Singapore (SG)

(21) Appl. No.: 19/136,355

(22) PCT Filed: Dec. 8, 2023
(86) PCT No.: PCT/US2023/083110

§ 371 Date: Jun. 6, 2025

Related U.S. Application Data
(60) Provisional application No. 63/386,669, filed on Dec. 8, 2022.
(60) Provisional application No. 63/492,657, filed on Mar. 28, 2023.

(51) Int. Cl. G02F 1/035; G02F 1/095; H10W 40/10; H10W 80/00; H10W 90/00; H10W 90/20

(52) U.S. Cl. CPC G02F 1/035; G02F 1/095; H10W 40/10; H10W 80/312; H10W 90/20; H10W 90/792

(57) ABSTRACT

Photonics has benefited immensely from advanced silicon manufacturing. By leveraging mature complementary metal-oxide-semiconductor (CMOS) process nodes, unprecedented device uniformity and scalability have been achieved at low cost. However, some functionalities, such as optical memory, Pockels modulation, and magneto-optical activity, are challenging or impossible to provide with group-IV materials alone. Heterogeneous integration promises to expand the range of capabilities within silicon photonics. Unfortunately, existing heterogeneous integration protocols are incompatible with the active silicon processes offered at most photonic foundries. Here, we by disclose a heterogeneous integration platform that enables waferscale, multi-material integration with active silicon-based photonics, with no change to the existing foundry process. Furthermore, this heterogeneous integration platform enables a class of high-performance devices, including: a grating coupler with peak coupling efficiency reaching 93%, an antenna with peak diffraction efficiency in excess of 97%, and a broadband adiabatic polarization rotator with conversion efficiency exceeding 99%.

### CROSS-REFERENCE TO RELATED APPLICATIONS

This application claims the priority benefit, under 35 U.S.C. § 119(e), of U.S. Application No. 63/492,657, entitled “Apparatus, Systems, and Methods of Heterogenous Photonic Integration” and filed Mar. 28, 2023, and of U.S. Application No. 63/386,669, entitled “Methods for CMOS Integration with Reduced Thermal Budget” and filed Dec. 8, 2022. Each of these applications is incorporated herein by reference in its entirety for all purposes.

### GOVERNMENT SUPPORT

This invention was made with government support under ECCS2028199 awarded by the National Science Foundation. The government has certain rights in the invention.

### BACKGROUND

Photonics has been one of the primary beneficiaries of advanced silicon manufacturing. By leveraging complementary metal-oxide-semiconductor (CMOS) fabrication processes, unprecedented device uniformities and scalability have been achieved at low cost. This has been attained without any compromise in device performance. For instance, ultra-low waveguide propagation loss (e.g., about 0.5 dB/cm), and optical modulation and photodetection with bandwidths in excess of 35 GHz can be readily demonstrated at the wafer-scale by several foundries around the world. However, due to the properties of group-IV materials, there are some functionalities that cannot be acquired natively on CMOS platforms. Heterogeneous silicon photonics, on the other hand, promises to expand the range of capabilities within silicon photonics. In spite of that, heterogeneous integration of non-CMOS materials on silicon is in general not compatible with standard foundry processes, and hence, any gains obtained may be offset by losses in performance and manufacturability.

### SUMMARY

Here, we disclose a multi-material optoelectronic platform that enables wafer-scale heterogeneous integration with active silicon photonics, with minimal or no change to existing foundry processes. In addition, our approach retains the back-end-of-the-line (BEOL) layers, enabling functionalities not otherwise possible. With increasing device integration densities, the degree of integration becomes increasingly limited by electronic and photonic packaging. This issue is exacerbated when both the electrical and optical I/O are occupying the frontside of the photonic chip. Aspects of the present technology address these issues through the monolithic integration of wiring redistribution layers as well as enabling bi-facial optical/electrical I/O. Furthermore, the present technology affords patterning both sides of photonic devices in comparison to contemporary photonic platforms where patterning only occurs from one side.

In some aspects, the techniques described herein relate to a method of making a photonic device that includes forming a photonic integrated circuit (PIC) on a first substrate (e.g., using industry-standard CMOS processes). The PIC has a frontside facing away from the first substrate and a backside facing the first substrate. Through-wafer electrical connections (e.g., through-silicon vias, through-glass vias, or a copper redistribution layer (RDL)) are formed extending through a second substrate from a first side of the second substrate to a second side of the second substrate. The frontside of the PIC is bonded to the first side of the second substrate. The second side of the second substrate is bonded to a functional carrier such that the functional carrier is in electrical communication with the PIC via the through-wafer electrical connections.

Bonding the frontside of the PIC to the first side of the second substrate may include connecting conductive pads on the frontside of the PIC to the through-wafer electrical connections of the first side of the second substrate. It may also, or alternatively, include forming a first direct bond interface (DBI) on the frontside of the PIC, forming a second DBI on the first side of the second substrate, and bonding the first DBI to the second DBI.

The functional carrier can be third substrate, in which case a complementary metal-oxide-semiconductor (CMOS) circuit can be formed in/on the third substrate. Forming the CMOS circuit can include forming at least one control element for a component in the PIC in a back end-of-line (BEOL) layer of the CMOS circuit.

A metal layer in the second substrate and/or the functional carrier (e.g., a BEOL layer or RDL) can be configured to reflect light incident on the backside of the PIC.

Bonding the frontside of the CMOS circuit to the second side of the second substrate may include bump bonding the frontside of the CMOS circuit to the second side of the second substrate. It could also include forming a first DBI on the frontside of the CMOS circuit, forming a second DBI on the second side of the second substrate, and bonding the first DBI to the second DBI.

The functional carrier can be an interposer, a chip carrier, or a (printed) circuit board, in which case bonding the second side of the second substrate to the functional carrier can include connecting the through-wafer electrical connections to the interposer, chip carrier, or (printed) circuit board via a ball grid array or a micro-bump array.

If desired, at least a portion of the first substrate can be removed to expose at least a portion of the backside of the PIC. This allows an optical connection to be formed directly to the backside of the PIC. It also allows a phase-change material, electro-optic material, liquid crystal material, Pockels material, magneto-optical material, nonlinear optical material, GeSn alloy, SiGeSn alloy, wide band gap semiconductor, narrow band gap semiconductor, two-dimensional material, piezoelectric material, or functional polymer to be disposed directly on the backside of the PIC. Alternatively, or additionally, a functional membrane can be disposed directly on the backside of the PIC.

This method can yield a photonic device that includes: a functional carrier; a wafer having a first side bonded to a frontside of the functional carrier; and a photonic integrated circuit (PIC) having a frontside bonded to a second side of the wafer and in electrical communication with the functional carrier via an electrical connection extending from the frontside of the PIC through the wafer to the functional carrier. The functional carrier can includes a CMOS circuit integrated with the substrate and having a frontside facing away from the substrate and connected to the electrical connection and a backside facing the substrate. The CMOS circuit can include a BEOL layer forming at least part of an element configured to provide spatial control of an electromagnetic field applied to a component in the PIC. The BEOL layer can also reflect light incident on a backside of the PIC into a waveguide formed in the PIC and/or reflect light from the waveguide through the backside of the PIC.

Alternatively, the functional carrier can be an interposer, printed circuit board, or chip carrier.

The PIC can be configured to receive electrical input via the electrical connection and to receive optical input via its backside.

The photonic device can also include a phase-change material, electro-optic material, liquid crystal material, Pockels material, magneto-optical material, nonlinear optical material, GeSn alloy, SiGeSn alloy, wide band gap semiconductor, narrow band gap semiconductor, two-dimensional material, piezoelectric material, and/or functional polymer disposed directly on the backside of the PIC.

The PIC can include an isolator, modulator, laser, and/or photodetector.

Another inventive method includes forming a PIC on a substrate with the PIC's frontside facing away from the substrate and its backside facing the substrate. The frontside of the PIC can be bonded to an electrical interface. Removing at least a portion of the substrate exposes at least a portion of the backside of the PIC, allowing an optical connection to be formed directly to the backside of the PIC or a phase-change material, electro-optic material, liquid crystal material, Pockels material, magneto-optical material, nonlinear optical material, GeSn alloy, SiGeSn alloy, wide band gap semiconductor, narrow band gap semiconductor, two-dimensional material, piezoelectric material, and/or functional polymer to be disposed directly on the backside of the PIC.

Another aspect of the present technology is a CMOS integration method that includes: (a) selectively depositing a material onto one or more patterned resistive micro-heaters (e.g., single-use micro-heaters and/or arrays of micro-heaters) at a low temperature to produce an amorphous, partly crystallized, or fully crystallized material; and (b) passing electric current through the micro-heaters to locally heat and anneal the deposited material and induce controlled crystallization, grain growth, defect removal, or impurity rejection in the absence of traditional global high temperature heat treatment.

The heater can be comprised of doped Si or Ge. The heater can be selected from silicides, transparent conducting oxides, graphene or other 2-D semi-metals, and metals. The heater can induce a random or a preferred crystalline growth orientation or a crystalline texture in films deposited on top of the heater, with heat treatment producing a textured film. And the heater can be transparent at the device operation wavelength.

The material deposited onto the micro-heaters can comprise a composition that forms an electro-optic crystal, magneto-optical crystal, phase transition oxide or chalcogenide, crystalline semiconductor, and compound semiconductor. For example, suitable electro-optic crystals include LiNbO₃, BaTiO₃, PbZrₓTi₁₋ₓO₃, SrTiO₃, other titanates or zirconates, and hafnium-zirconium oxide. Suitable magneto-optical crystals include magneto-optical perovskites or garnets, where the magneto-optical garnets are comprised of cerium-substituted yttrium iron garnet (Ce:YIG), bismuth-substituted yttrium iron garnet (Bi:YIG), or doped terbium iron garnets. A suitable phase transition oxide or chalcogenide can be comprised of VO₂ or GeₓSb_{y}Te_{z}. And a suitable crystalline semiconductor can be comprised of Si, Ge, or III-V materials such as GaAs.

In other cases, the material deposited on the micro-heater can include a non-photonic material, in which case the micro-heater may be opaque. For instance, the material can be a magnetic garnet, such as A₃Fe₅O₁₂ or A₃Fe₅₋ₓBₓO₁₂, where A is selected from Y, rare earth, and Bi, and B is a Fe substituent selected from Ga, Al, and Co. The material could also include a complex oxide selected from spinels Fe₃O₄, CoFe₂O₄, and Fe₂O₃; a perovskite ABO₃ wherein A is selected from Sr, Ba, Y, rare earth, and Bi, and B is a transition metal; an antiferromagnets selected from α-Fe₂O₃ and NiO; a ferroelectric selected from BiFeO₃, lead zirconate titanate PZT, lead magnesium niobate/lead titanate PMN-PT, and BaTiO₃; a two phase magnetoelectric structure selected from BiFeO₃ and CoFe₂O₄; a superconductor comprised of yttrium barium copper oxide YBCO; a magnetically-doped oxide comprised of TiO₂/Co; or a paramagnet comprised of TbGa garnet TGG.

If desired, films deposited on areas outside the desired heater regions can be removed via lift-off.

All combinations of the foregoing concepts and additional concepts discussed in greater detail below (provided such concepts are not mutually inconsistent) are contemplated as being part of the inventive subject matter disclosed herein. In particular, all combinations of claimed subject matter appearing at the end of this disclosure are contemplated as being part of the inventive subject matter disclosed herein. The terminology explicitly employed herein that also may appear in any disclosure incorporated by reference should be accorded a meaning most consistent with the particular concepts disclosed herein.

### BRIEF DESCRIPTIONS OF THE DRAWINGS

The skilled artisan will understand that the drawings primarily are for illustrative purposes and are not intended to limit the scope of the inventive subject matter described herein. The drawings are not necessarily to scale; in some instances, various aspects of the inventive subject matter disclosed herein may be shown exaggerated or enlarged in the drawings to facilitate an understanding of different features. In the drawings, like reference characters generally refer to like features (e.g., functionally similar and/or structurally similar components).

FIGS. 1A and 1B show two possible variants of the present technology, indicating the cross-sectional structure of a bi-facial optical/electrical input/output (I/O), multi-material platform. The layers of the platform are (FIG. 1A) CMOS wafer, direct-bond interconnects (DBIs), through-silicon vias (TSVs)/through-glass vias (TGVs), DBI, photonic integrated circuit (PIC) (including BEOL layers), and multi-material integration layer and (FIG. 1B) interposer/printed circuit board (PCB)/carrier, ball grid array (BGA), TSV/TGV, DBI, PIC (including BEOL layers).

FIGS. 2A-2D illustrate a process flow involved in the fabrication of the embodiment shown in FIG. 1A. FIG. 2A shows a PIC wafer, TSV/TGV, and CMOS wafer fabricated separately, utilizing standard fabrication process flows. FIG. 2B shows DBI formation on both sides of the TSV/TGV, PIC wafer, and CMOS wafer. DBI surface planarization and passivation can be implemented to reduce the surface roughness to increase bonding yield. FIG. 2C shows bonding of the PIC wafer and CMOS wafer to both sides of the TSV/TGV. Suitable bonding methods include direct dielectric/Cu bonding, hybrid bonding as well as thermocompression bonding. FIG. 2D shows PIC wafer substrate removal.

FIG. 2E shows heterogenous integration of functional materials to the backside of the photonic device layers.

FIGS. 3A-3E show a process flow involved in the fabrication of embodiment in FIG. 1B. FIG. 3A shows a PIC wafer, TSV/TGV, and interposer/PCB/carrier fabricated separately, utilizing standard fabrication process flows. FIG. 3B shows DBI formation on the electrical contact pads of the PIC wafers and one side of the TSV/TGV. DBI surface planarization and passivation can reduce the surface roughness to increase bonding yield. Solder bump formation on the other side of the TSV/TGV. FIG. 3C shows bonding of the PIC wafer (BEOL side) to the TSV/TGV (DBI side) and bonding of interposer/PCB/carrier to the TSV/TGV via solder bumps. FIG. 2D shows PIC wafer substrate removal. FIG. 3E shows heterogenous integration of functional materials to the backside of the photonic device layers.

FIG. 4 shows an embodiment of the multi-integration aspect indicated by heterogeneously integrating phase change materials with an add-drop racetrack resonator.

FIG. 5A shows a simulated magneto-optical cross-sectional distribution of the in-plane magnetic field Hₓ with respect to a magneto-optical heterogeneous waveguide overlaid on depictions of the magneto-optical materials, photonic device and BEOL layer.

FIG. 5B shows the optical spectrum of an isolator that is heterogeneously integrated with magneto-optical materials and uses the BEOL metal to magnetize the magneto-optical material. The solid (dashed) curve represents the spectrum of a Mach-Zehnder modulator for light propagating in the forward (backward) direction.

FIG. 6A shows a cross-sectional heterostructure of a patterned magneto-optical material, heterogeneously integrated with a photonic device, where the isolation in transverse electric (TE) polarization is attained the H_{y} magnetic fields enabled by the BEOL layers and the magneto-optical material.

FIG. 6B shows a cross-sectional heterostructure of a magneto-optical material film, with a photonic device, where the isolation in TE polarization is attained the H_{y} magnetic fields enabled by the BEOL layers and the magneto-optical material.

FIG. 6C shows the simulated magneto-optical cross-sectional distribution of the H_{y} magnetic field with respect to the magneto-optical materials, photonic device, and BEOL layer of the heterostructure in FIG. 6A.

FIG. 6D shows the simulated magneto-optical cross-sectional distribution of H_{y} magnetic field with respect to the magneto-optical materials, photonic device and BEOL layer is illustrated, for the heterostructure in FIG. 6B.

FIG. 7A shows heterogeneous integration of liquid crystals with the photonic layer, with localized electric-field control and subsequent index change in the liquid crystals through the BEOL layers, where locally induced index change in the liquid crystal is enabled by localized electric field control.

FIG. 7B shows a top-view illustration of the liquid crystal heterogeneously integrated with a 1×3 multi-mode interferometer, where darker shading indicates voltage-induced index changes in the liquid crystal that change in the multiple mode interferometer's interference condition, resulting in a splitting ratio of 70, 0, and 30% at the outputs.

FIG. 7C shows the device of FIG. 7B set to output splitting ratios of 10, 80, 10%.

FIG. 8A shows a cross section of a heterostructure of Pockels material, photonic device, and electric field applied through the photonic device's highly doped semiconductor and the BEOL layers, where a localized electric field is applied through the highly doped semiconductor layer and the BEOL layers.

FIG. 8B is a plot of the optical spectrum of a racetrack resonator integrated with the heterostructure of FIG. 8A, with voltages of 0, 0.5, and 1 V applied across the BEOL layer within the heterostructure.

FIG. 9 shows a top view of a heterogeneously integrated photonic device with periodically poled X⁽²⁾ materials. The periodic poling is enabled through the highly doped semiconductor and the BEOL layers as indicated; poling resolution can be implemented via the critical dimensions of the photonic chip fabrication process (e.g., 100 nm).

FIGS. 10A and 10B illustrate the transfer of a thin membrane (e.g., a functional membrane or 2-D material) from epitaxial life-off that can be as thin as the nanometer range.

FIG. 10C shows a heterostructure with a functional membrane integrated with a photonic device layer and exemplary doped semiconductor and BEOL layers.

FIG. 10D shows a heterostructure with a 2-D material integrated with a photonic device layer and exemplary doped semiconductor and BEOL layers.

FIGS. 11A-11C illustrate epitaxial integration of elemental alloys with a photonic device. FIGS. 11A and 11B show opening of windows, exposing the template onto which the material will be grown, and growth at high temperature of a high-quality, thick layer, respectively. Both Si and Ge layers can be grown on a heterostructure. FIG. 11C shows metal electrodes that may then be deposited onto the newly grown material. These electrical connections can be re-routed through the entire stack through connections with doped-Si. Current/electric-field/magnetic-field control of the epitaxially integrated, photonic device heterostructure, where the arrangement of the doped semiconductor and the subsequent BEOL layers depends on the on the desired functionality and epitaxial material.

FIG. 12A shows the etch profile for a high-efficiency grating coupler commensurate with standard, wafer-level foundry processes. The etch profile (Y-X plane cut), obtained via inverse design for mode-matching to the fiber mode, shows the first BEOL metal layer, which is vertically spaced 1.1 μm away from an optical fiber core and is used as a reflector. (The RDLs can also be used as reflectors.) A 220 nm full silicon etch is implemented to avoid variation in grating performance attributed to non-uniformity in etching depths. The direction of coupled-fiber light is illustrated, angled at 10° with respect to the surface normal. The frontside and backside of the PIC wafer are labeled for clarity.

FIG. 12B shows the electric-field distribution of a lightwave in the Y-X plane as the Lightwave is coupled from the optical fiber core to the waveguide.

FIG. 12C is a plot of the wavelength-dependent coupling loss (left axis) and back reflection (right axis) of the grating coupler of FIG. 12A simulated using 3-D FDTD. 1-dB bandwidth of the grating coupler is 32 nm with a peak coupling efficiency of 93 % (insertion loss=0.32 dB).

FIG. 13A illustrates top (left) and side (right) views of a high-efficiency nanoantenna. A 130 nm etch is used for the grating teeth, which is a standard etch depth used for forming silicon slabs in silicon-based photonic foundries. The BEOL layer, spaced about 1 μm from the photonic device layer, increases directionality (side view). As illustrated in the side-view schematic, the lightwave propagates along the waveguide and is diffracted to the mirror plane to the photonic chip frontside. Only the first metal layer is illustrated.

FIG. 13B is a plot of transmission against wavelength, with a 1 dB bandwidth of over 200 nm, for the nanoantenna of FIG. 13A.

FIG. 13C is a plot of the electric-field distribution of the lightwave as the lightwave propagates along the waveguide and is diffracted to the backside via the nanoantenna of FIG. 13A.

FIG. 13D is a plot of the near-field emission of the nanoantenna of FIG. 13A.

FIG. 14A shows bottom (left), top (middle), and cross-sectional views (right) of a polarization rotator that leverages on the additional degree of photonic device patterning.

FIG. 14B shows the cross-sectional electric-field distribution of the waveguide mode as it travels along the polarization rotator in FIG. 14A, where the input polarization is TE₀₀ and TM₀₀ in the top and bottom planes, respectively.

FIG. 14C shows the electric-field distribution in the propagation plane as TE00 (top) and TM₀₀ (bottom) input travels along the rotator and is rotated to TM₀₀ and TE₀₀ polarizations, respectively.

FIG. 15 shows a baseline CMOS device architecture and CMOS fabrication process with a reduced thermal budget: (1) fabrication of an on-chip integrated heater in doped Si; (2) deposition of functional materials in an amorphous state followed by encapsulation; and (3) in situ annealing to heat treat the functional materials via resistive heating on the heater.

FIG. 16A shows an example doped Si heater design: an n-doped region also serves as a rib waveguide for light guiding.

FIG. 16B shows simulated top-view (top panel) and cross-sectional (bottom panel) temperature profiles when the heater is operating in a stationary state, showing good thermal confinement of the heating region.

FIG. 17A is an optical micrograph showing as-deposited amorphous Bi-Tb iron garnet film on a doped Si heater.

FIG. 17B is an optical micrograph showing the Bi-Tb iron garnet after in situ annealing to induce crystallization.

FIG. 17C shows Raman spectra of Bi-Tb iron garnet films crystallized by rapid thermal annealing in a furnace; the arrows indicate the characteristic Raman peaks of crystalline Bi-Tb iron garnet.

FIG. 17D shows the Raman spectrum of a Bi-Tb iron garnet film crystallized on chip, implying successful crystallization by the integrated micro-heater.

FIGS. 18A and 18B show an example integration process: (1) fabrication of an integrated heater on silicon-on-insulator (SOI); (2) trench etching to selectively remove the Si substrate; (3) resist coating within the etched trench; (4) resist exposure and development; (5) etching of the buried oxide layer followed by resist stripping; (6) functional material deposition and encapsulation; and (7) in situ annealing to heat treat the functional materials via resistive heating on the heater.

FIGS. 19A and 18B shows another example integration process: (1) fabrication of an integrated heater on SOI and a handler substrate with embedded TSVs; (2) bonding to a handler substrate with TSVs; (3) thinning of handler substrate to expose TSVs from the top (4) removal of the starting Si substrate; (5) removal of the buried oxide layer; (6) functional material deposition and encapsulation; and (7) in situ annealing to heat treat the functional materials via resistive heating on the heater.

FIG. 20 shows a variant of the integration process applied to hybrid bonded materials: (1) the target material bonded to the structure shown in step (5) of the process shown in FIG. 19; (2) (optional) substrate removal; and (3) (optional) patterning of the functional material layer.

### DETAILED DESCRIPTION

Heterogeneous integration (HI) combines two or more material technologies into a single chip-scale platform. In integrated photonics, HI is typically achieved by hybrid bonding or monolithic deposition. As an example of hybrid bonding, III-V die-to-wafer bonding has been employed to integrate III-V light sources, isolators, modulators, and detectors with silicon photonics platforms. Monolithic growth or deposition has also been implemented to integrate a wide variety of non-Si materials onto Si PICs. These classical integration schemes demand physical access to the PIC devices, which allows the optical modes in the photonic circuit to have a large spatial overlap with the heterogeneously integrated materials, thereby enhancing their optical performances while reducing device footprint. To date, heterogeneous integration has been performed either on devices without the standard BEOL stack or inside windows or trenches etched into the BEOL dielectric layers. The former does not provide access to BEOL interconnects for advanced electronic-photonic integration. The latter approach, on the other hand, involves opening a custom window, incurring extra cost and processing time. Opening a custom window exposes a waveguide core, which elevates the risk of contamination and damage. In the case of deposited materials, uniform film deposition into the window can be challenging especially when the window etched into the backend dielectrics has a small area or a high aspect ratio. Moreover, both approaches deprive the devices of access to BEOL layers on top. As disclosed here, the absence of BEOL layers also severely constrains the device optical and electromagnetic functionalities that can be realized.

Here, we disclose bi-facial multi-material/optoelectronic platforms and fabrication methods that make possible the realization of: (1) wafer-scale, heterogeneous integration of multi-materials within the platform, enabling an unprecedented range of functionalities (e.g., non-volatile optical memories, light non-reciprocity, photodetection in the mid-infrared); (2) application of localized electrical and magnetic fields on-chip via the BEOL layers; (3) electrical and optical I/O decoupling, increasing the limits on device integration; and (4) an additional degree of waveguide patterning, which enables a new class of devices, such as polarization rotators, rotator-free isolators, and 90° I/O grating couplers. Suitable materials for integration include, but are not limited to, phase-change materials, electro-optic materials, liquid crystal materials, Pockels materials, magneto-optical materials, nonlinear optical materials, GeSn or SiGeSn alloys, wide band gap semiconductors (e.g., SiC, ZnO, or diamond), narrow band gap semiconductors (e.g., HgCdTe or a lead salt), 2-D materials (e.g., van der Waals crystals), piezoelectric materials (e.g., lead titanate and derivatives, polyvinylidene fluoride, potassium sodium niobate, etc.), or functional polymers.

The architecture and integration process described herein differs from other wafer backside HI approaches in that the optical and electrical I/Os are routed separately from top and bottom surfaces, respectively, of the photonic chip, and that the BEOL layers realize optical and electromagnetic functions (e.g., optical reflectors or local electrical/magnetic field control) besides serving as simple electrical connections. In other backside HI approaches, the handler substrate bonded onto the starting wafer acts merely as a mechanical support and carries no active electrical functions.

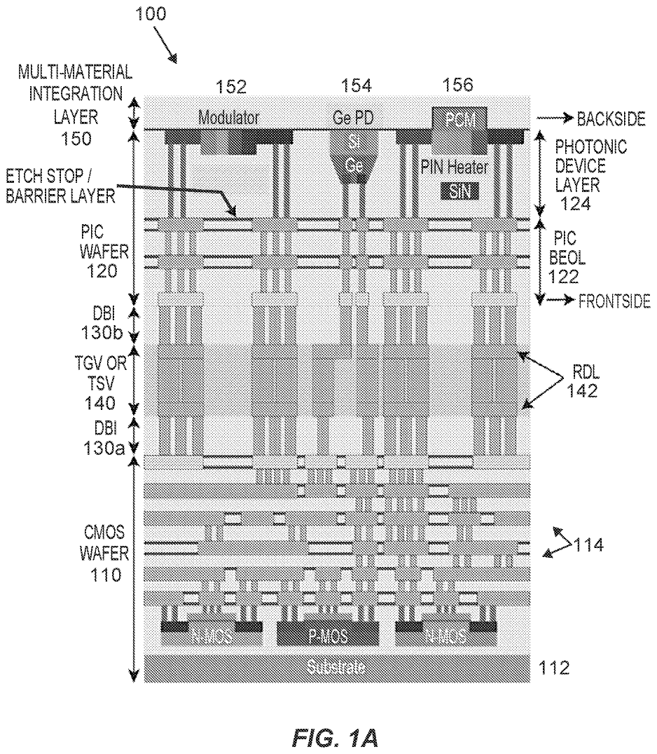

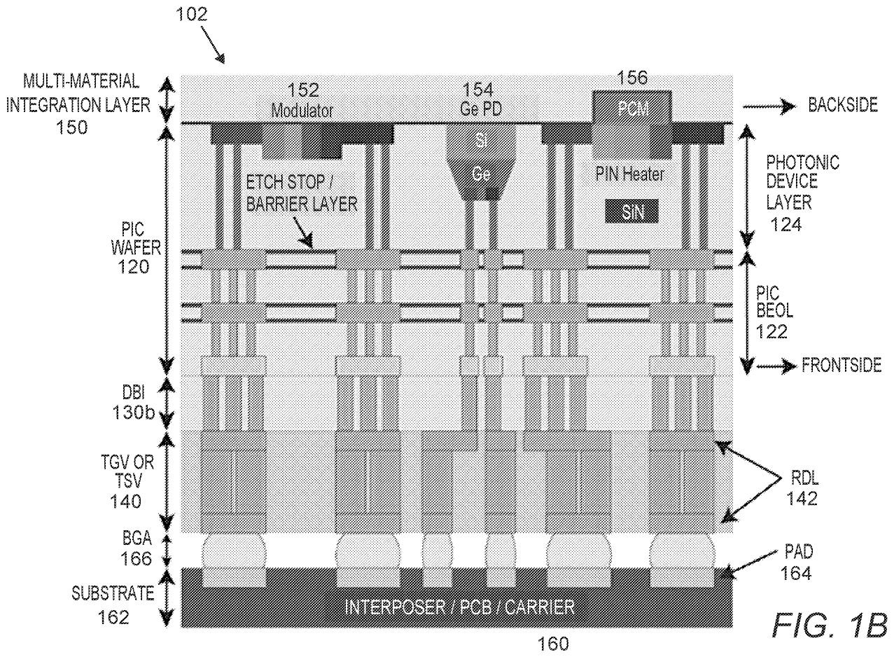

FIG. 1A illustrates a bi-facial, multi-material/optoelectronic platform architecture 100 that includes:
1. A CMOS wafer 110 on a substrate 112, typically Si. Metal interconnects 114 on the CMOS wafer may integrate redistribution layers.
2. A photonic integrated circuit (PIC) wafer 120, which contains:
   2.1 PIC BEOL layers 122, where localized electric and magnetic fields is applied through these layers 122;
2.2 One or more photonic device layers 124, which typically includes silicon nitride, silicon, and germanium layers. Other CMOS compatible materials such as aluminum nitride can be implemented within the photonic device layer(s) 124. The photonic device layers 124 are stacked on top of each other and can be etched selectively where desired, for example, to grow one material (e.g., GeSn) on another (e.g., Ge) or deposit another material (e.g., PCM) on a substrate (e.g., Si).
3. Two direct bond interconnect (DBI) layers 130a and 130b: One DBI layer 130b is adjacent to the PIC wafer 120 and the other DBI layer 130a is adjacent to the CMOS wafer 110.
4. A secondary substrate 140 containing through-silicon/glass vias (TSV/TGVs), which are bonded to the BEOL layers 122 of the PICs in the PIC layer 120. Redistribution 12. layers (RDLs) 142 can be implemented in the TSV/TGV to reduce wiring density within the photonic integrated circuit and CMOS.
5. If desired, a multi-material layer 150 or platform can be heterogeneously integrated on top of the photonic device layer 124. Heterogeneous integration can be implemented at any of the photonic device layers 124 (e.g., Si, SiN, or Ge). Materials for heterogeneous integration, while include but are not limited to, LPCVD SiN fabricated via the damascene process, phase change materials (PCMs) 156 (e.g., Sb₂S₃, Sb₂Se₃, GSST, GST, VO₂), magneto-optical materials (e.g., cerium-substituted yttrium iron garnet or Ce:YIG, Bi:YIG, terbium gallium garnet, etc.), liquid crystals, Pockels media (e.g., barium titanate, lithium niobate, lithium tantalate), and materials with high X⁽²⁾ coefficient (e.g., lithium niobate, III-V, III-N, lead zirconate titanate, etc.). In addition, epitaxial growth of materials such as GeSn, SiGeSn, crystalline oxides/chalcogenides, or other III-V compounds can be implemented at the backside of the photonic device layers 124. These materials can be used to form modulators 152, photodetectors 154, and/or other devices on the backside of the PIC wafer 120.

FIG. 1B illustrates an alternative embodiment 102 of the inventive architecture. Like the embodiment 100 shown in FIG. 1A, this alternative embodiment 102 includes the PIC wafer 120 with PIC BEOL layer(s) 122 and photonic device layer(s) 124. The multi-material integration layer 150, possibly with a modulator 152, Ge photodetector 154, and/or PCM 156, sits on the photonic device layer 124. The PIC BEOL layer(s) 122 are bonded to the DBI layer 130b, which in turn is bonded to the TSV/TGV secondary substrate 140. Unlike FIG. 1A where the PIC wafer 120 interfaces directly with the CMOS stack, however, the TSV/TGV secondary substrate 140 is connected via a ball grid array (BGA) 166 or micro-bump array to an interposer, printed circuit board (PCB), or chip carrier 160. The interposer/PCB/carrier 160 includes a substrate 162 with conductive pads 164 that mate to and provide electrical connections to the balls in the BGA 166. If desired, the interposer/PCB/carrier 160 can include or connect to an external circuit (not shown). The electrical I/O from the PIC wafer 120 is connected to the external circuit through the BGA 166 or micro-bump array and interposer/PCB/carrier 160.

In the following, we disclose a cohort of inventive device designs enabled by the platform architectures described above, including:
1) Localized electric and magnetic field control and manipulation on-chip through the BEOL layers as part of the PIC, with or without a doped semiconductor.
2) Nonvolatile photonic memories realized through the heterogeneous integration of PCMs on top of an electrothermal heater.
3) Transverse magnetic (TM) and transverse electric (TE) optical isolators enabled by the heterogeneous integration of magneto-optical materials. The isolators can be electrically biased through the BEOL layers. Rotator-free TE isolation is demonstrated through precise manipulation of the spatial distribution of magnetic fields using the BEOL layers.
4) Photonic devices based on the heterogeneous integration of liquid crystals, where precise control of electric fields through the semiconductor layer and the connected PIC BEOL layers facilitates localized index control pertaining to the liquid crystal. The optical functionalities on the photonic device can then be controlled via evanescent coupling.
5) High-speed optical phase shifters and modulators enabled via the heterogeneous integration of material with Pockels effect. Localized electric field application can be enabled through the doped semiconductor and the PIC BEOL layers.
6) Poling of materials with significant X⁽²⁾ coefficients, such as electro-optic polymers or glasses, through a doped semiconductor and the PIC BEOL layers.
7) Heterogeneous integration of ultra-thin membranes (e.g., as low as nanometer-scale) via epitaxial lift-off.
8) Highly efficient I/O grating couplers (coupling efficiency=93%) using the PIC BEOL layers as reflectors to increase directionality. An inverse design is implemented to design each localized grating period and duty cycle for mode matching to the fiber Gaussian mode.
9) Highly efficient (diffraction efficiency=97%) and ultra-broadband nanoantenna (1 dB bandwidth=217 nm) using the PIC BEOL layer as the reflector. Grating period and duty cycle determined via swarm optimization.
10) Asymmetrical waveguides created via a bi-facial patterning process, where a polarization rotator with polarization conversion efficiency in excess of 99% is demonstrated, leveraging on the additional degree of photonic device patterning.

### Heterogeneous Photonic Integration Techniques

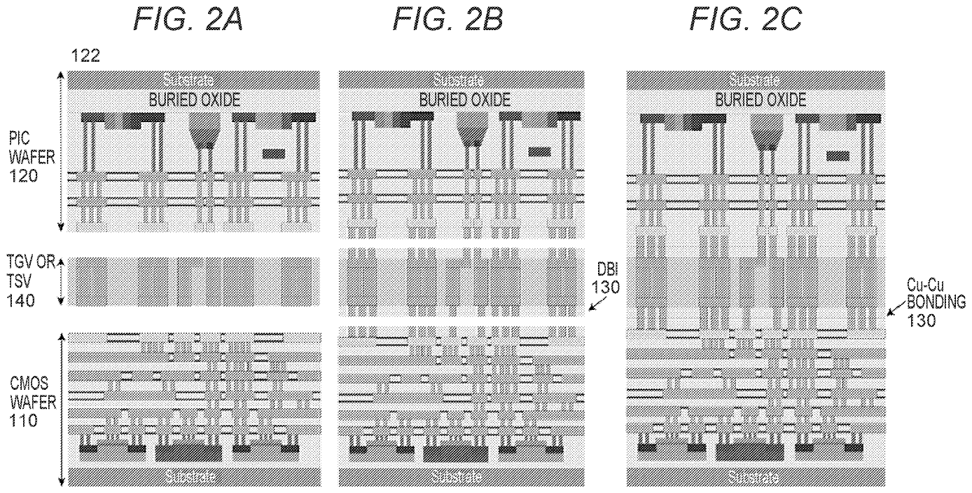

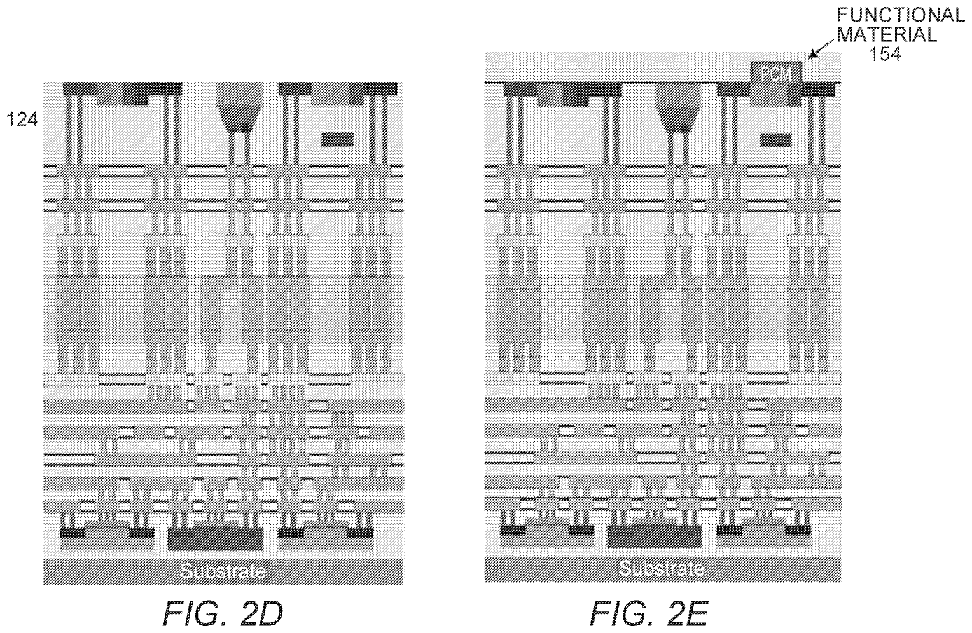

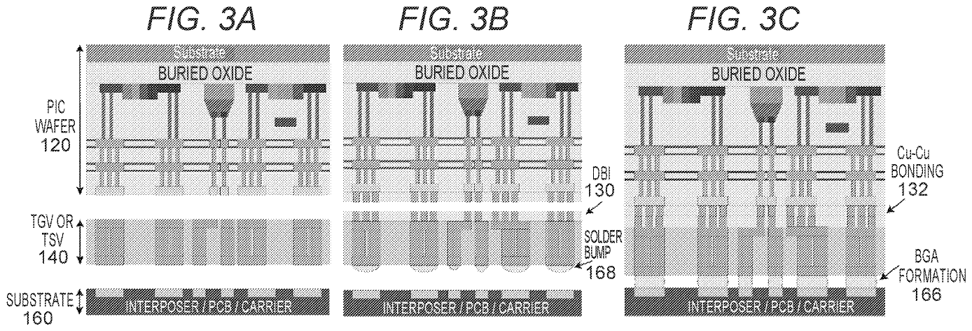

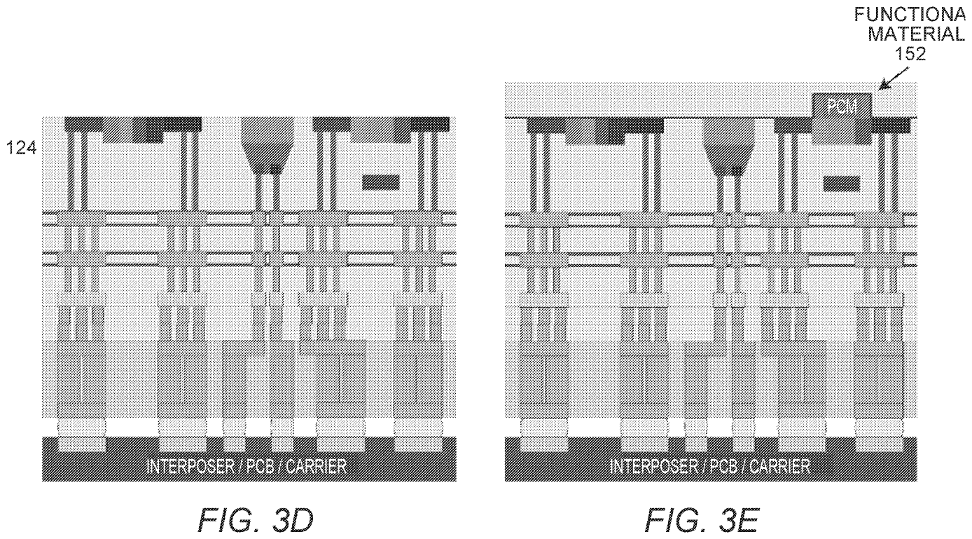

The platforms 100 and 102 shown in FIGS. 1A and 1B can be fabricated via the inventive methods in FIGS. 2A-2E and 3A-3E, respectively. As shown in FIG. 2A, the TGV/TSV substrate 140, PIC wafer 120, and CMOS wafer 110 are fabricated separately in photonic and CMOS foundries following standard protocols with minimal or zero customization (FIG. 2A). DBIs 130 are formed on both sides of the TSV/TGV, as well as the electrical contacts on the CMOS wafer and PIC wafer at the BEOL side (FIG. 2B). Subsequent planarization and passivation can be performed at the DBI surfaces to reduce the extent of surface roughness, greatly enhancing bonding yield. Both sides of the TSV/TGV DBIs substrate/wafer are bonded to the CMOS wafer and the PIC wafer, facing its BEOL side, e.g., with Cu—Cu bonding 132 (FIG. 2C). Other suitable wafer bonding methods include direct dielectric/Cu bonding, hybrid bonding, and thermocompression bonding. The PIC wafer 120 includes a substrate 122 that is removed (FIG. 2D) to expose the backside of the photonic device layer(s) 124 as described in greater detail below. If desired, functional material, such as electro-optic material, magneto-optic material, or PCM 154 can be formed or deposited on the exposed backside (FIG. 2E) to create one or more integrated optoelectronic devices again as described in greater detail below.

Making the embodiment 102 of FIG. 1B starts, similarly, with fabrication of the TGV/TSV substrate 140, PIC wafer 120, and interposer/PCB/carrier 160, e.g., according to standard manufacturing processes (FIG. 3A). DBI formation 130, planarization, and passivation are carried out on the electrical contacts of PIC wafer 120 on the BEOL side, as well as one side of the TSV/TGV substrate 140. Solder bumps 168 are formed on the other side of the TSV/TGV substrate 140 (FIG. 3B). The PIC wafer 120 is bonded to the DBIs 130 on the TSV/TGV substrate 140 using the abovementioned approaches (e.g., direct dielectric/Cu bonding, hybrid bonding, thermocompression bonding), and the other side of the TSV/TGV substrate 140 is bonded to the interposer/PCB/carrier 160 through the solder bumps 168. The PIC wafer 120 can be bonded to the TSV/TGV wafer 140 via solder bumps as well (not shown).

After the bonding steps (FIGS. 2A-2C, 3A-3C), the PIC wafer is inverted, and the original PIC wafer substrate 122 is removed (FIGS. 2D and 3D). For instance, if the PIC is fabricated on a silicon-on-insulator (SOI) wafer, the Si is removed via mechanical lapping and/or chemical etching, and then the buried oxide layer is further thinned down to a small thickness (to enable evanescent interactions with the photonic device layer) or completely removed to expose the photonic device layer 124. The backside substrate removal process results in the formation of a surface with high surface smoothness due to the lack of device topology (waveguides). This enables the heterogeneous integration of various photonic materials (e.g., PCM 152) on the surface using the technology platform, within the CMOS-compatible framework, at the wafer level (FIGS. 2E and 3E). In addition, the low surface roughness that is intrinsic to this process could be beneficial for direct bonding of various materials and 2-D material or nanomembrane integration without requirements on subsequent planarization. Multiple materials can be integrated on the surface, including by heterogeneous transfer or bonding and monolithic deposition.

### Photonic Devices With Heterogeneously Integrated Materials

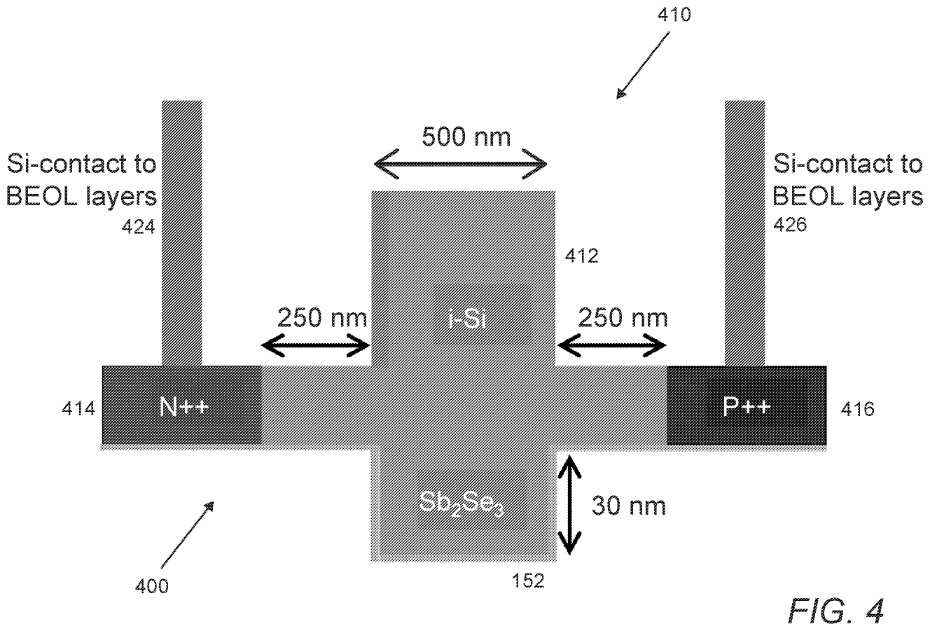

FIG. 4 shows an embodiment of the multi-material integration aspect of the present technology in the form of a nonvolatile optical phase shifter 400. This phase shifter 400 includes phase change material (PCM) 452 heterogeneously integrated on a doped SOI heater 410. The PCM 452 is deposited on the backside of an intrinsic Si portion 412 of the SOI layer after substrate removal. This intrinsic Si portion 412 is between an n⁺⁺ doped region 414 and a p⁺⁺ doped region 416, which are coupled to the BEOL layer via Si contacts 424 and 426, respectively. By varying the voltage and pulse duration applied to the Si contacts 424 and 426, the PCM 452 can be switched reversibly between amorphous and crystalline states, resulting in a refractive index change. The electrical signal can be applied to the Si contacts 424 and 426 from the CMOS wafer, to the DBI, TSV/TGV with or without RDL, DBI again and through the photonic BEOL to the photonic device layer. Besides thermal modulation of HI materials and photonic devices, other use cases for the integrated heater include, but are not limited to local post-integration heat treatment to promote HI material quality (e.g., crystallization, grain growth, defect annihilation, or zone refining).

An advantage of the inventive architecture is that localized electric field or magnetic field can be applied via the PIC BEOL metal (or doped semiconductor) layers, which are retained in this inventive process rather than removed as in a traditional HI process. Following heterogeneous or epitaxial multi-material integration, electric or magnetic fields may be applied to the heterogeneously integrated material. Examples of applications where such field control may be beneficial include but are not limited to electro-optic modulators, magneto-optic modulators, liquid crystal-based devices, poling of ferroelectrics, spintronics, and more. As an example, for the case of optical isolators, magneto-optical materials can be heterogeneously integrated to the platform. Methods of heterogeneous integration include bonding with single crystalline magneto-optical materials or polycrystalline magneto-optical materials or their deposition via pulsed laser deposition or sputtering.

Following the heterogeneous integration of magneto-optical material, an optical isolator can be magnetically biased via two approaches. First, there is the application of an external magnetic field to the magneto-optical material. Second, another approach includes the deposition of metal layers on a substrate of single-crystalline magneto-optical material, and then subsequently running current through the metal layers. In such an implementation, the substrate has a large thickness (e.g., up to 10 μm), so the deposited metal wires are far away (e.g., 500 nm or more) from the magneto-optical material and high operating current is used to bias the magneto-optical material. Moreover, forming metal wires on the magneto-optical substrate constitutes post-processing, which limits the scalability of the approach in terms of both manufacturing and the capability of generating fields of complex spatial patterns. Conversely, the present technology makes use of the BEOL layers that are part of the PIC BEOL stack, in which the minimum vertical spacing between the metal layers and the magneto-optical materials can be as low as about 1 μm.

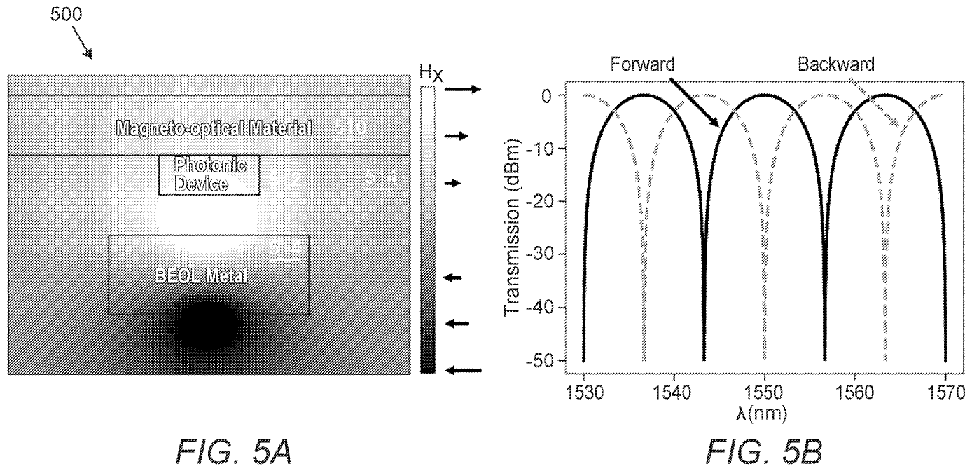

FIG. 5A illustrates an isolator 500 with magneto-optical material 510 heterogeneously integrated on a waveguide core (photonic device) 512, which provides one arm of a Mach-Zehnder interferometer. The magneto-optical material 510 is deposited on the exposed backside of the waveguide cores 512 of the Mach-Zehnder interferometer. These waveguide cores 512 are formed in a buried oxide layer 514 on a semiconductor substrate (not shown). One or more PIC BEOL metal layers 516 run through or under a portion of the buried oxide layer 514, e.g., within about 1 μm of the magneto-optical material 510. Assuming a conservative value for the Faraday rotation of the magneto-optical material 510 as about 3000 deg/cm, which is commensurate to Faraday rotation for Ce: YIG, the magneto-optical material 510 can produce a non-reciprocal phase shift of about 2 rads/mm or more. For a phase shift of Tt radians, this corresponds to Mach-Zehnder arms 512 that are about 785 μm long (into and out of the plane of FIG. 5A).

FIG. 5A also shows magneto-optical simulations of the cross-sectional in-plane magnetic field perpendicular to the direction of light propagation (Hₓ) in a heterogeneously integrated waveguide, where significant magnetic field strength can be experienced by the waveguide.

FIG. 5B is a plot of transmission versus wavelength for waves propagating forward (solid line) and backward (dashed line) in the isolator 500 of FIG. 5A under driving currents of 50 mA in a push-pull configuration. FIG. 5B shows a z phase shift between the forward-and backward-propagating waves, indicating high optical isolation (e.g., about 40-50 dB).

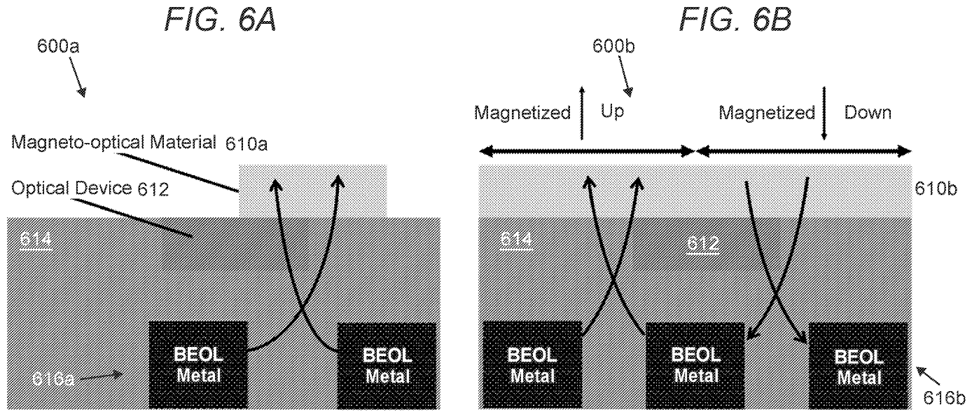

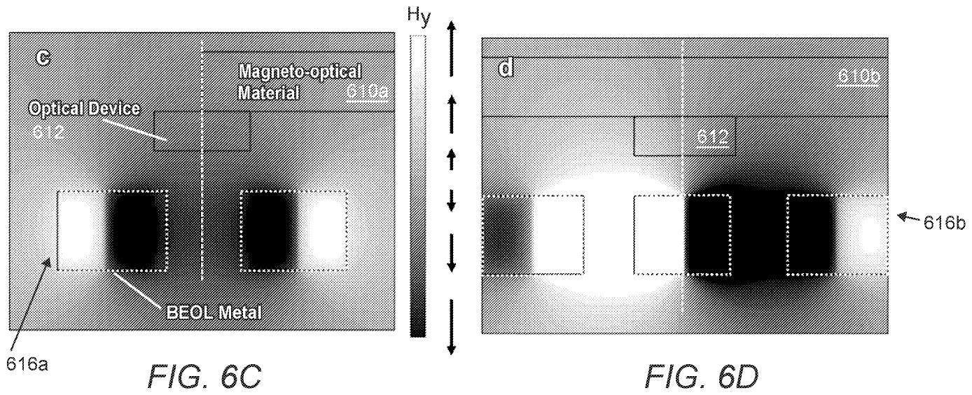

FIGS. 6A-6D illustrate more embodiments of multi-material integration with localized application of electric/magnetic fields. The number of BEOL layers and their proximity to the photonic device layers enables a high degree of control in terms of magnetic/electric field control. This enables complex, localized field manipulation on-chip. More specifically, FIGS. 6A-6D illustrate two different versions of a magneto-optical material heterogeneously integrated with a TE waveguide. FIGS. 6A and 6B show cross sections of the wafers/devices 600a and 600b, respectively, and FIGS. 6C and 6D illustrate the out-of-plane (with regards to the wafer) magnetic field component H_{y} for FIGS. 6A and 6B, respectively.

In FIG. 6A, the device 600a includes heterogeneously integrated magneto-optical material 610a on the backside of the platform. The magneto-optical material 610a has been selectively patterned, e.g., with pulsed laser deposition and subsequent focused ion beam etching, so that it partially overlaps a TE waveguide (optical device) 612a formed in a buried oxide layer over two BEOL metal layers 616a. FIG. 6C shows the out-of-plane magnetic field component H_{y} where the two BEOL layers 616a, together with the magneto-optical material 610a, induce left-right asymmetry with regards to the TE waveguide 612a.

In FIG. 6B, the device 600b includes heterogeneously integrated, unpatterned magneto-optical material 610a on the backside of the platform. This unpatterned magneto-optical material 610a can take the form of a magneto-optical film or bulk crystal bonded directly to the backside. The magneto-optical material 610a completely overlaps a TE waveguide (optical device) 612b formed in a buried oxide layer over three BEOL metal layers 616b. The PIC BEOL metal layers 616b are arranged to induce high left-right asymmetry as indicated in FIG. 6D, i.e., the single-crystalline magneto-optical material 610a is magnetized in opposite directions on the left and right sides with respect to the center plane (vertical dashed line).

For magneto-optical materials integrated with TE waveguides as in FIGS. 6A-6D, a non-reciprocal phase shift as high as 2.09 rads/mm can be attained assuming Faraday rotations of 4000 deg/cm, a conservative figure for typical cerium-doped yttrium iron garnet. These values are comparable to those obtained in the case of TM waveguides, thereby enabling polarization rotator-free TE isolation. The devices in FIGS. 5A, 6A, and 6C also enable 18. cryogenic optical modulation in TM and TE polarizations, a useful feature for low-temperature quantum photonics applications. This addresses a problem faced by traditional modulators based on silicon: the thermo-optic coefficient of Si falls significantly at lower temperatures, while the efficiency of the plasma dispersion effect plummets due to carrier freeze-out. In contrast, the Faraday rotation of magneto-optical material may increase as temperature decreases.

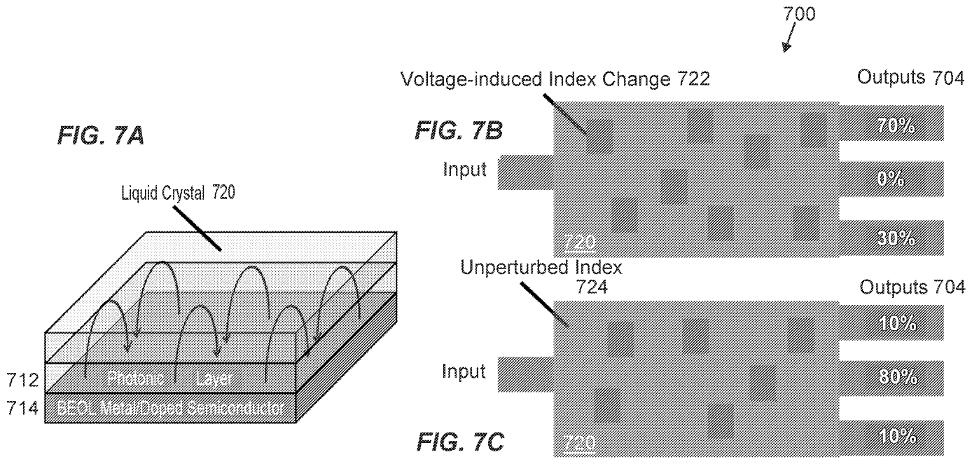

FIGS. 7A-7C illustrate another multi-material embodiment that exploits localized electric/magnetic field application with one or more BEOL layers 714, this time for locally modulating the refractive index of liquid crystal material 720. Similar to the embodiments above, the liquid crystal material 720 is integrated on the backside, above a photonic device layer 712, which in turn is on the BEOL layer(s) 714. The liquid crystal material 720 can be integrated on the backside by forming liquid crystal cells or microfluidic chambers using SU-8, polymethyl methacrylate, or cyclic olefin copolymer. The PIC BEOL layers 714, in appropriate proximity (in plane and vertically) to the liquid crystal material 720, apply localized voltages to different portions of the liquid crystal material 720, resulting in localized, voltage-induced changes in the liquid crystal's refractive index. An optical mode propagating in the photonic device layer 712 interacts evanescently with the voltage-induced index change, possibly by refracting, reflecting, or diffracting.

FIGS. 7B and 7C show how localized, voltage-induced index changes in heterogeneously integrated liquid crystal material 720 can change the splitting ratio of a 1×3 multi-mode interference (MMI) coupler 700. Without any applied voltage, the liquid crystal material 720 has a nominal unperturbed index 724. Applying a voltage to the liquid crystal material 720 with the BEOL layer(s) 714 produces a spatially localized change or perturbation 722 in the liquid crystal material's refractive index. The interference condition in the MMI coupler 700 can be controlled through the locally induced changes in refractive index of the integrated liquid crystal 720, for example, to vary the ratio of optical power at the three outputs 704 as shown in FIGS. 7B and 7C. More generally, an array of electrodes based on PIC BEOL layers 714 can be embedded underneath the PIC photonic device layer and electrostatically control the 2-D refractive index distribution on the PIC photonic device layer, enabling dynamic programming of topologically optimized photonic devices.

Many of the materials in the PIC photonic device layers (e.g., silicon) commensurate with large scale photonic foundries are centrosymmetric and do not exhibit the Pockels effects. 19.

As a result, contemporary commercial silicon-based modulators operate based on the plasma dispersion effect. Simultaneous changes in the real and complex refractive indices of silicon as a result of carrier modulation may impose difficulties when using more complex modulation formats. Furthermore, plasma dispersion modulators are limited by carrier mobilities. Phase shifters and modulators based on the Pockels effect are not subject to these limitations.

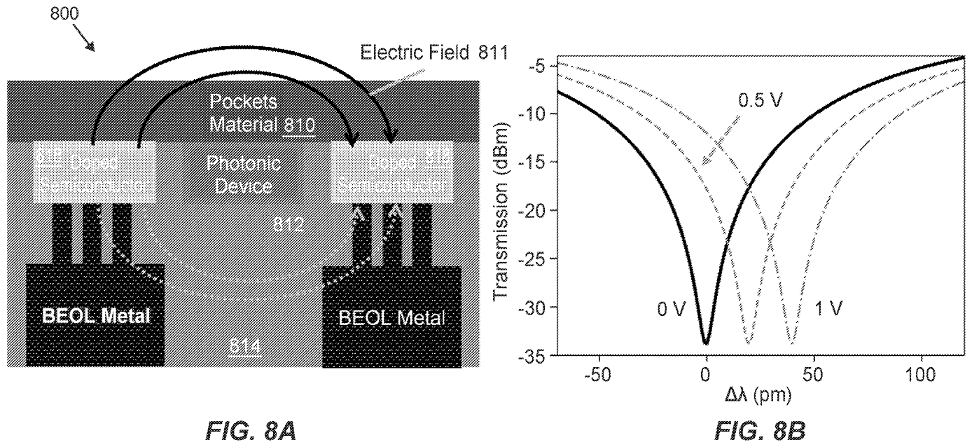

FIG. 8A shows a cross section of a heterostructure 800 with Pockels material 810, such as barium titanate, lithium niobate, or lithium tantalate, heterogeneously integrated onto the backside of a photonic device 812, such as a Mach-Zehnder interferometer, microring, racetrack, microdisc resonator, or photonic crystal cavity. The photonic device 812 is formed in a buried oxide layer 814 on patterned BEOL metal layers 816 and between a pair of doped semiconductor regions 818, which are coupled to respective portions of the BEOL metal layers 816. Applying an electric field 811 across the Pockels material 810 via the patterned BEOL metal layers 816 and doped semiconductor regions 818 modulates the phase of light propagating through the photonic device 812 (i.e., into and/or out of the plane of FIG. 8A). This enables the realization of Pockels-based high-speed phase shifters and optical intensity modulators.

FIG. 8B is a plot of simulated transmission versus wavelength at different voltages (electric field strengths) for the heterostructure 800 in FIG. 8A with an all-pass racetrack resonator as the photonic device 812. The racetrack resonator had a radius of 20 microns and two straight sections each 100 μm long through the heterostructure. The resonator had a quality factor of about 5000, which corresponds to a photonic-limited lifetime of about 45 GHz. As indicated in FIG. 8B, the application of voltage (0, 0.5, 1.0 V) across the BEOL layers 816 (FIG. 8A) red-shifts the racetrack resonance. This implies that high-speed optical modulation can be enabled by applying a radio-frequency (RF) voltage across the heterostructure. The bandwidth of the optical modulation is not limited by the Pockels effect, but rather, the photon lifetime and RF mismatch. The photon lifetime can be reduced further by decreasing the quality factor of the racetrack resonator. Furthermore, RF matching circuits can be implemented in any of the BEOL layers, TSV/TGV RDL layers, or CMOS metal layers, facilitating high-speed Pockels-based modulation.

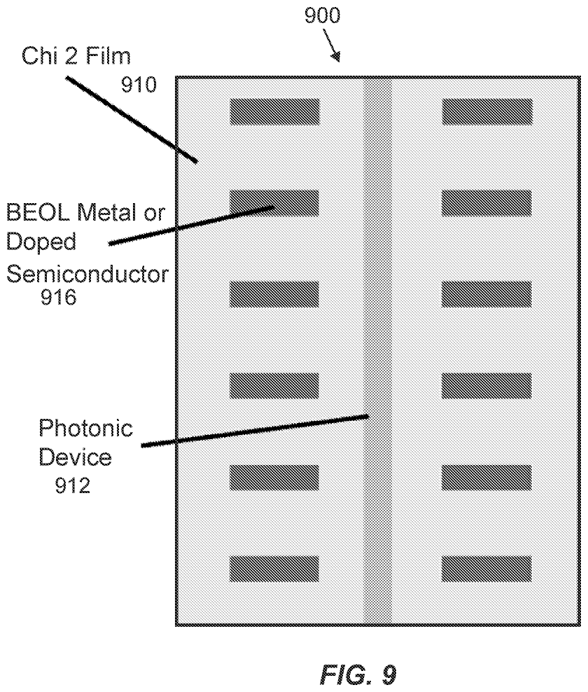

FIG. 9 illustrates who the same heterostructure configuration in FIG. 8 can be applied to (periodically) poling materials, e.g., electro-optic polymers or glasses, to induce X⁽²⁾ nonlinearity. Suitable electro-optic materials include but are not limited to lithium niobate, III-V materials, III-N materials, and lead zirconate titanate. Periodically poled X⁽²⁾ materials have applications in telecommunications, quantum optics, and nonlinear beam control, among other things. To date, periodic poling has not been integrated via a CMOS-compatible framework at scale. Unlike pre-poled lithium niobate on silicon, an inventive post-poling process enables patterning resolution limited only by the critical dimension of the silicon manufacturing process, which can be much finer than the spatial resolution of other patterning processes.

More specifically, FIG. 9 is a plan view of a heterostructure 900 with a film or layer of X⁽²⁾ nonlinear material 910 disposed on a photonic device 912 (e.g., waveguide(s)), which is in a buried oxide over one or more patterned BEOL layers 916 (the heterostructure's DBIs, TSV/TGV, CMOS layers are omitted for clarity) or highly doped semiconductor regions. The BEOL metals 916 and/or highly doped semiconductor regions are arranged in a periodic pattern for periodically poling the X⁽²⁾ nonlinear material 910.

The back-removal process detailed above enables the monolithic formation of highly planar, smooth surfaces. As a result, surfaces with low root-mean-square (RMS) roughness (e.g., <0.5 nm) can be attained without the use of pillar structure and subsequent chemical mechanical polishing (CMP). This provides a high-quality surface for the transfer of high-quality functional thin films that may be as thin as nanometers without risking rupturing the transferred material. Functional thin films can be transferred on the backside of the platform (adjacent to the PIC photonic device layer) in a stress-free fashion. Suitable thin films include, but are not limited to, 2-D materials or van der Waals (VdW) solids (e.g., graphene, transition metal dichalcogenides), Pockels materials (e.g., barium titanate, lithium niobate, lithium tantalate) and III-V membranes (e.g., InP, GaN, GaSb, GaAs).

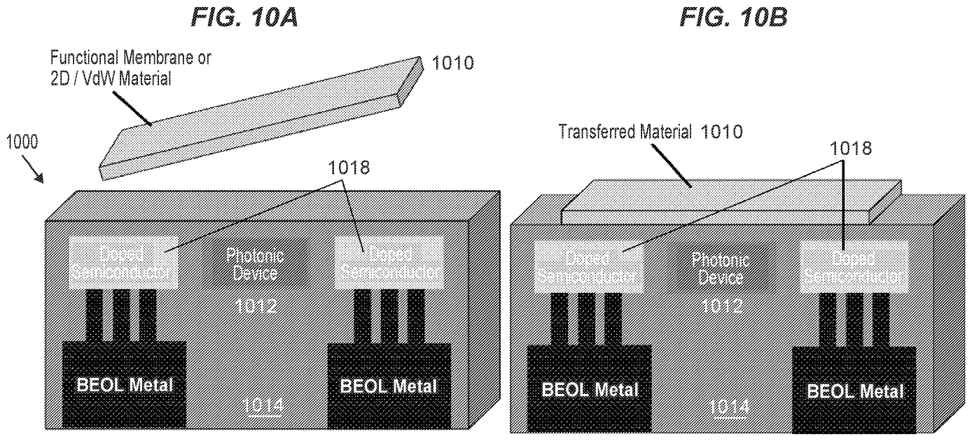

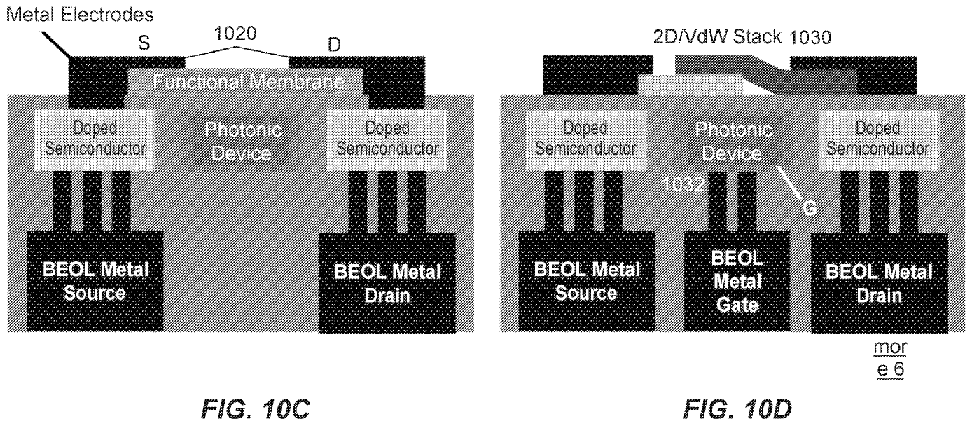

FIGS. 10A-10D illustrate how a functional membrane or 2D/VdW film 1010 can be transferred onto the backside of a platform that includes a photonic device 1012, patterned BEOL metal 1016, and doped semiconductor regions 1018 in a buried oxide layer 1014. Removing a substrate (now shown) from the buried oxide layer 1014 leaves a smooth surface that readily accommodates the functional membrane or 2D/VdW film 1010 as shown in FIGS. 10A and 10B. If desired, source(S) and drain (D) electrodes 1020 can be formed or deposited on, overlapping with, or next to the functional membrane 1010 as in FIG. 10C. These electrodes 1020 can be electrically connected to the patterned BEOL metal 1016 via the doped semiconductor regions 1018 and used to apply an electric field to the functional membrane 1010, e.g., for modulating the functional membrane's optical properties. FIG. 10D shows that the backside can also supports more sophisticated structures, such as a stack 1030 of 2D/VdW materials, along with more sophisticated electrode arrangements, such as a BEOL metal gate 1028 coupled directly to a photonic device 1032.

An inventive platform also provides direct access to single-crystalline materials (Si and Ge) for HI of single-crystalline semiconductors via epitaxial growth. Growth can be performed on Si directly after removal of the PIC substrate and the buried oxide layer to expose the SOI layer. An additional etching step on the SiGe structures to remove the Si device layer can further expose single-crystalline Ge, which facilitates growth of crystals with a larger lattice constant than that of Si (e.g., GaAs, AlGaAs, GeSn, and SiGeSn). The silicon oxide dielectrics surrounding the Si or Ge regions can act to confine the growth in selective area epitaxy, enabling device pattern formation without an extra lithographic patterning step. For example, epitaxial growth of GeSn on silicon can involve a three-step process given the large lattice mismatch between the two. The process can be initiated by a two-step process for the formation of a Ge layer (low temperature thin layer followed by high-quality thick layer growth at high temperatures). Then GeSn can be grown on top of the Ge layer.

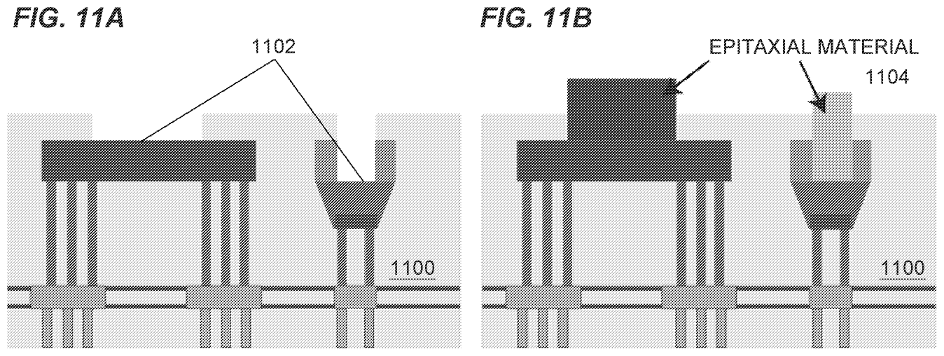

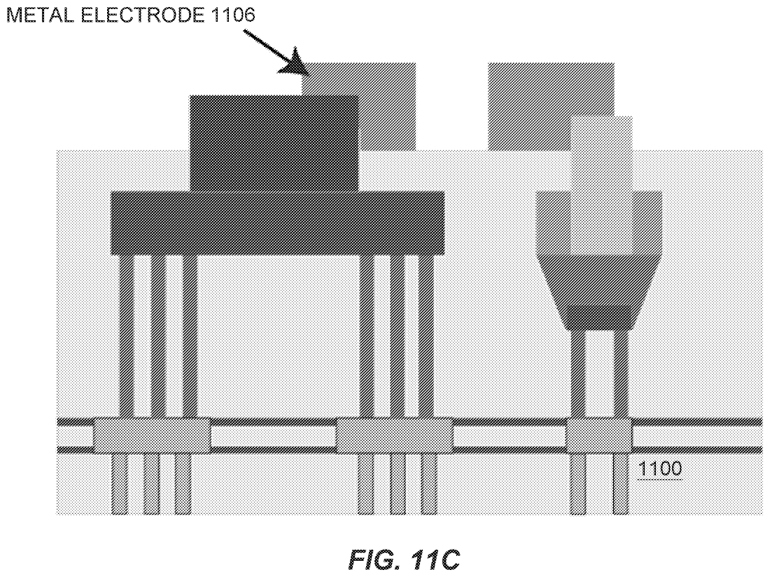

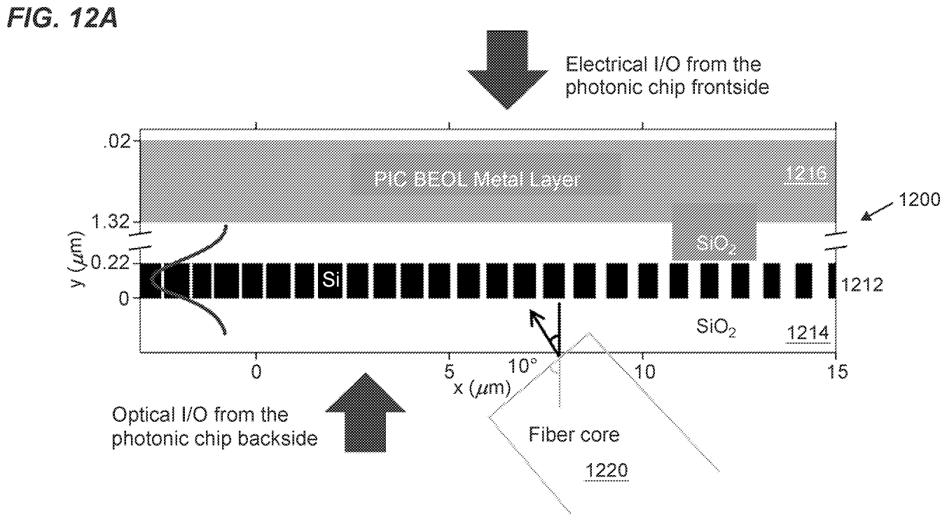

FIGS. 11A-11C illustrate epitaxial integration of GeSn. FIG. 11A illustrates etching that removes the silicon substrate, buried oxide (BOX), and the silicon device layer from a heterostructure 1100 to expose one or more surfaces, such as epitaxially foundry-grown germanium surfaces 1104. In FIG. 11B, epitaxial material 1106, such as Ge, Si, or GeSn, is grown on the exposed surfaces 1102. Performing epitaxial integration of GeSn as shown in FIGS. 11A and 11B eliminates one step of the conventional two-step epitaxial growth process by exploiting the foundry-grown Ge layer. In addition, the GeSn layer can be grown at significantly lower temperatures compatible with CMOS backend, reducing adverse effects of GeSn growth on the entire layer stack. Electrical contacts to the Ge layer, which is part of the PIC BEOL stack, can also be used to contact the resulting Ge-GeSn structures. If desired, metal electrodes 1106 can be formed on the Ge-GeSn structures as shown in FIG. 11C.

### Bi-Facial Electrical and Optical Input/Output (I/O) and Bi-Facial Patterning

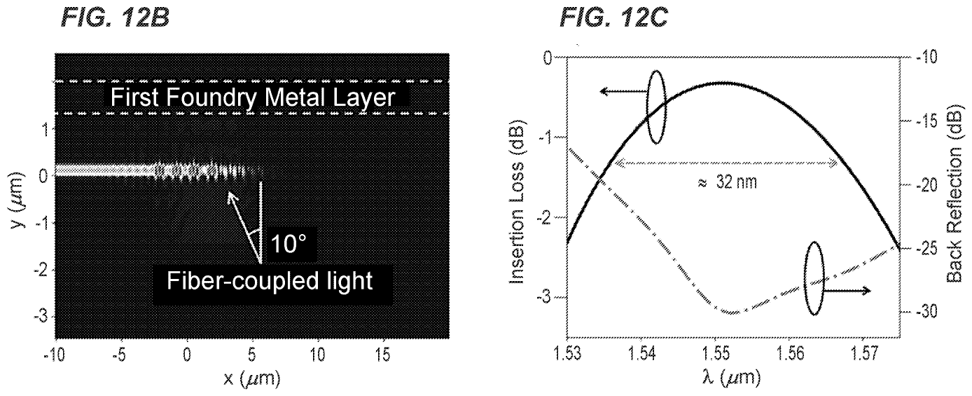

FIGS. 12A-12C show how the present technology enables bi-facial electrical and optical input/output (I/O). Unlike in a conventional PIC, where both optical and electrical I/Os connect from the frontside of the PIC, in our architecture the electrical I/Os are connected through the TSV/TGVs to the CMOS wafer bonded to the frontside of the PIC and the optical I/Os can be configured on the backside of the PIC. In this configuration, the PIC BEOL metal 22. layers can act as reflective mirrors to facilitate highly efficient optical I/O by increasing diffraction directionality. Using the BEOL layers as the optical reflector enables directionality to be increased on a wafer scale.

FIG. 12A illustrates a side view of an integrated I/O device 1200 with electrical I/O on the frontside and optical I/O on the backside. The integrated I/O device 1200 includes a BEOL metal layer 1216 on the frontside of the device 1200 over a photonic device, such as a waveguide with a grating structure 1212, formed in a silicon dioxide layer 1214. (For sake of simplicity, FIG. 12A shows only the photonic device layer 1212 and the closest BEOL layer 1216.) The grating is implemented in a 220 nm-thick layer of silicon, with a full silicon etch used to form the grating teeth. The localized grating periods and duty cycles are determined via inverse photonic design.

In operation, the grating 1212 diffracts light from an optical fiber 1220 that illuminates the backside into the waveguide. Some of this light propagates through the grating 1212 without diffracting, reflects off the backside of the BEOL layer 1216 toward the grating 1212, and either diffracts into the waveguide or propagates out of the device. The grating 1212 can also diffract light from the waveguide into the optical fiber 1220. At the same time, the frontside of the BEOL layer 1216 can be coupled to external electrical contacts (not shown) for electrical I/O.

FIG. 12B shows the electric-field distribution of light coupled from the optical fiber 1220, angled at 10° from the normal, to the waveguide through the I/O photonic device 1200. The maximum coupling efficiency of the photonic I/O device is 93 %, which is obtained as a result of increased directionality from using the BEOL metal layers 1216 as a reflector. FIG. 12C is a plot of the insertion loss versus wavelength for coupling light into and of the device via the grating embedded in the waveguide. It shows that the 1 dB bandwidth of the I/O photonic device is about 32 nm, with back reflection as low as about −30 dB.

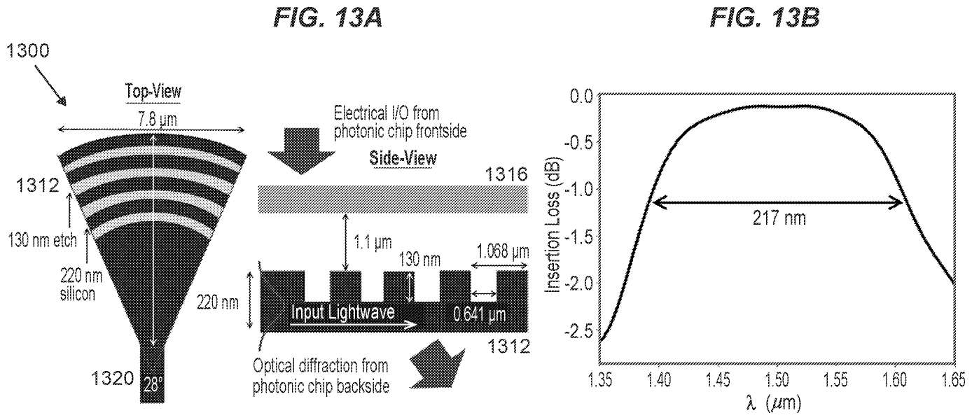

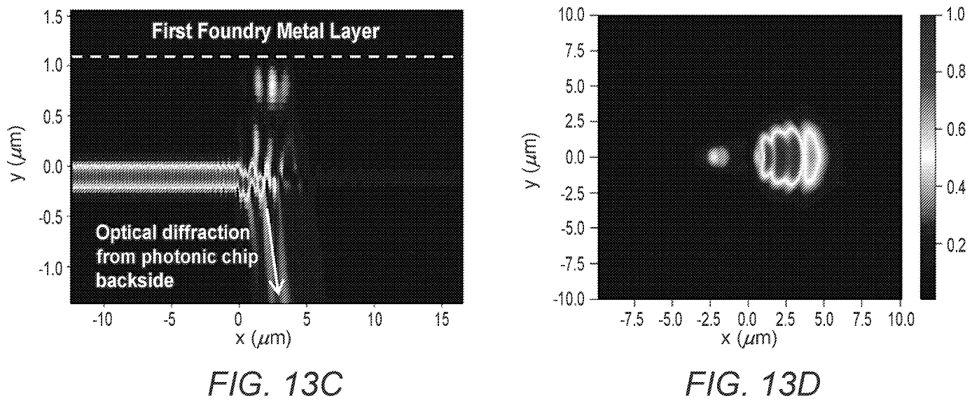

FIGS. 13A-13D illustrate a nanoantenna 1300 that uses the bi-facial electrical and optical I/O aspects of the present technology. The nanoantenna 1300 includes a grating structure 1312 that is coupled to a photonic waveguide 1320 and situated beneath the one or more BEOL metal layers 1316. In the same fashion as shown in FIG. 12A, the BEOL layer 1316 acts as an optical reflector, reflecting light diffracted out of the grating structure 1312 out the backside and increasing the nanoantenna's diffraction directionality and diffraction efficiency.

FIG. 13B is a plot of insertion loss versus wavelength for the grating structure 1312 in FIG. 13A. By using the BEOL layer 1316 as an optical reflector, the grating structure has a maximum diffraction efficiency as high as about 97% and a 1 dB bandwidth of about 217 nm. FIGS. 13C and 13D shows side and top views, respectively, of the electric field distribution of the lightwave propagates through the photonic waveguide 1320 and diffracting out of the backside via the grating structure 1312. This nanoantenna diffraction is from the backside, decoupling electrical and optical I/O to the frontside and backside, respectively. This is especially useful in beam forming applications that use large arrays of nanoantenna and integrated phase controllers. The phase controllers can be actuated electronically via electronics connected to the frontside of the technology stack, making it possible to pack the nanoantennas more densely. Furthermore, the nanoantenna in FIGS. 13A-13D has double the Field-of-View (FoV) of contemporary beam steering systems.

Yet another unique feature of the inventive platform is that an additional photonic device patterning step can be performed via the PIC wafer backside. This (optional) extra photonic device patterning step enables bi-facial patterning, where structures are patterned from both front and back sides. In bi-facial patterning, because the substrate is removed and the backside of photonic devices (e.g., Si waveguides) are exposed, lithography can be performed on the backside of the devices. This enables two sets of patterning steps, one from frontside done in the frontend before substrate removal, and one from the backside after substrate removal. Through this bi-layer patterning, it is possible to define structures that would otherwise be impossible to make conventionally, for example “floating” Si (e.g., the top 110 nm is left, but the 110 nm on the bottom are etched from the back).

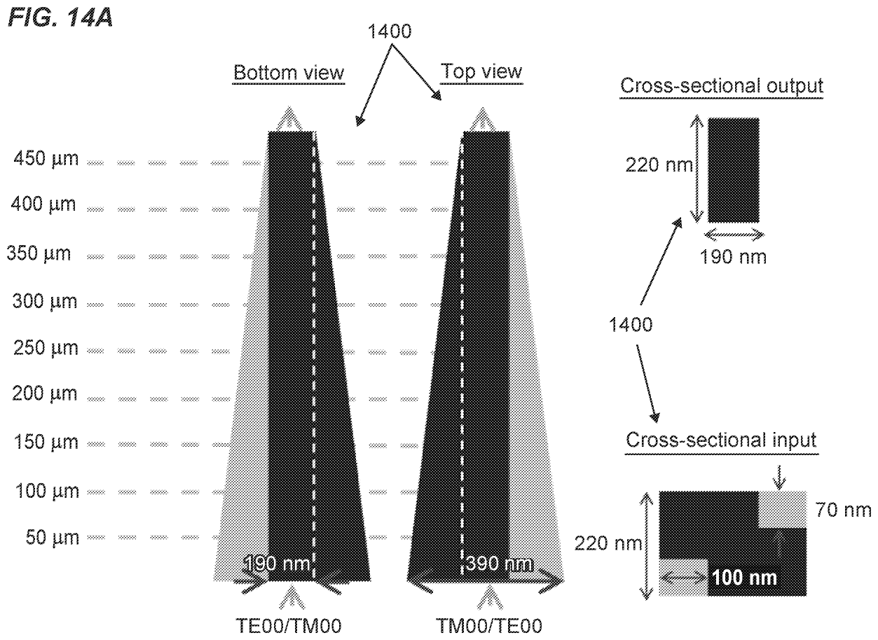

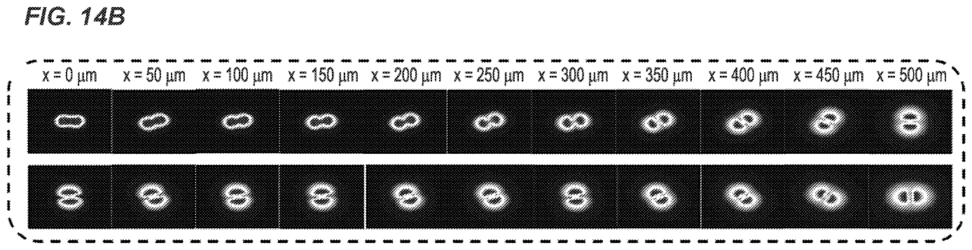

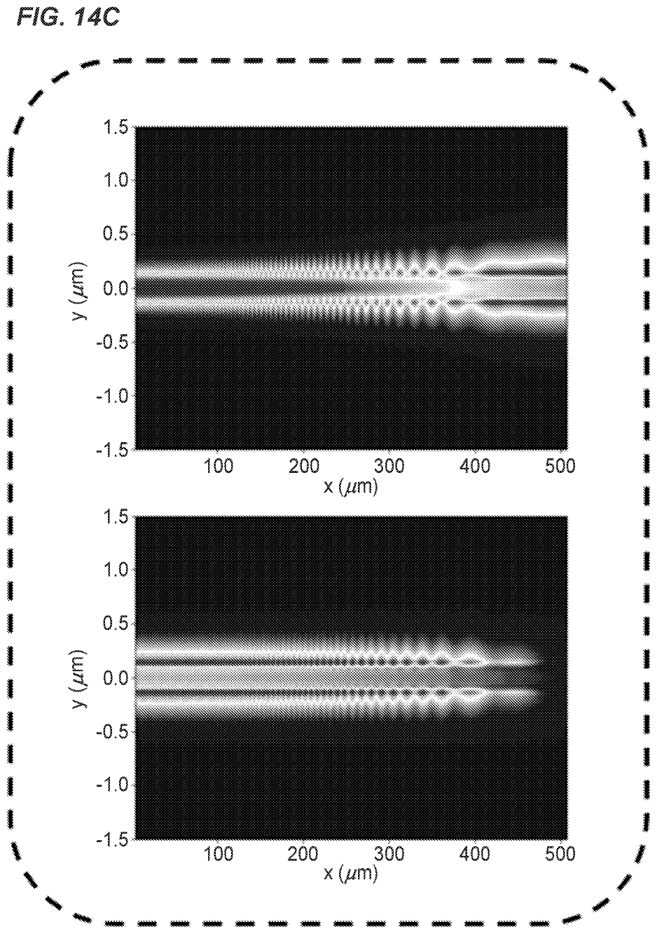

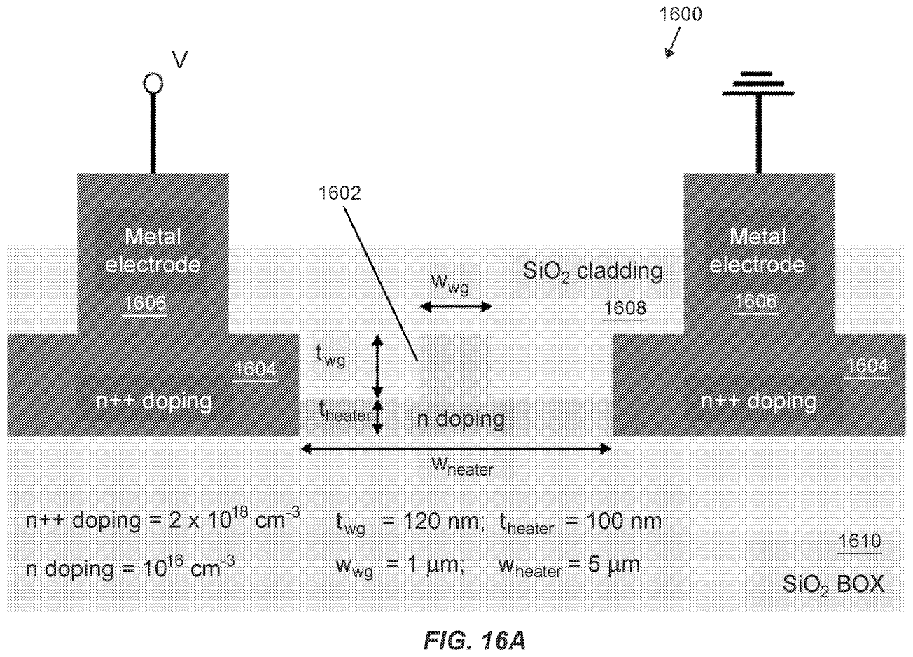

FIGS. 14A-14C illustrate a polarization rotator 1400 that leverages this bi-facial patterning process. FIG. 14A shows top and bottom views and input and output cross sections of the polarization rotator 1400. The polarization rotator 1400 increases in width smoothly from its input to its output. Its index profile, however, is asymmetric as indicated by the shading in FIG. 14A, where darker shading indicates a higher refractive index and lighter shading indicates a lower refractive index. As viewed from the bottom or top, the polarization rotator 1400 has a bottom layer that is 70 nm thick with a triangular low-index region that borders the left side of a trapezoidal high-index region; a top layer that is also 70 nm thick with a triangular low-index region that borders the right side of a trapezoidal high-index region; and a central layer that is 80 nm thick and that is entirely high-index material. The two triangular low-index regions are each right triangles and each have sides with lengths of 100 nm and 500 nm The top and bottom panels of FIG. 14B show the cross-sectional evolution of the optical mode as the lightwave propagates along the polarization rotator 1400, where the input polarization is TE and TM polarized, respectively. The rotator reaches polarization conversion efficiencies in excess of about 99%. The top and bottom plots of FIG. 14C show the cross-sectional distribution of the electric field when the input polarization is TE and TM, respectively.

### CMOS Integration With Reduced Thermal Budgets

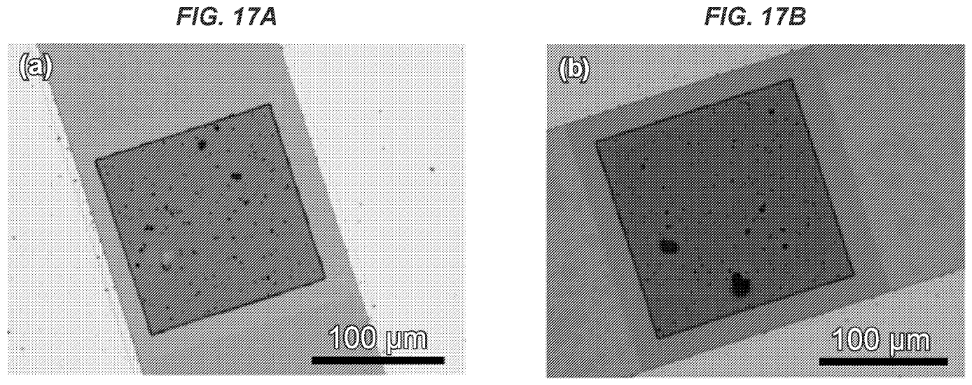

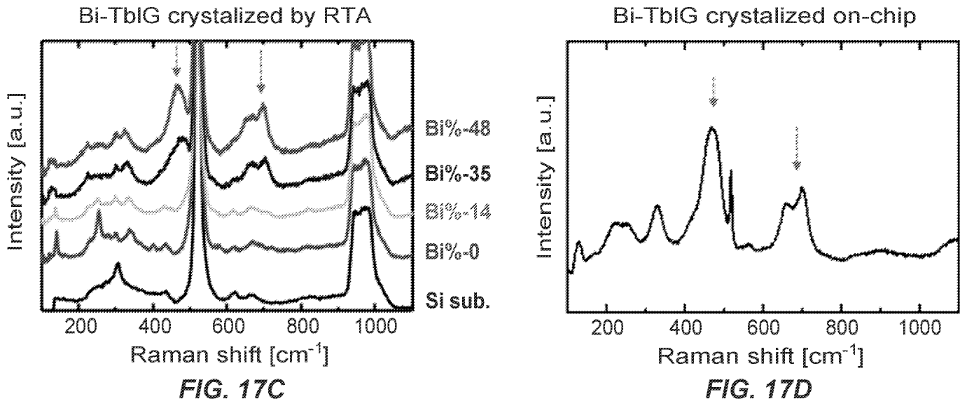

FIGS. 15-20 illustrate methods of integrating materials that traditionally demand excessive thermal budgets (e.g., materials that transform into a functional crystalline form at high temperatures or to undergo grain growth at high temperatures) into photonic devices. Instead of resorting to heat treatment of the entire wafer or chip, the material is selectively deposited onto patterned resistive micro-heaters at a low temperature and subsequently annealed by passing electric current through the heaters later in the fabrication process. The heat treatment can induce controlled crystallization, grain growth, defect removal, or impurity rejection to enhance the film quality. The resistive heater(s) heat the material locally at a device scale, without subjecting other devices on the same wafer/die to high temperatures. Moreover, the resistive heaters can be single-use devices since they may not be used again during the device's life once the material has been properly heat treated. This single-use attribute further allows unconventional heater designs or operating conditions that are normally not permitted by traditional design rules.

Using resistive heaters to heat materials locally does not require any change to standard photonic foundry fabrication processes. Put differently, fabrication processes involving resistive heaters are ‘zero-change’ processes for realizing backend heterogeneous integration of new materials without any modifications to standard photonic foundry fabrication process flows. Instead, these processes simply involve removal of the substrate to enable access to the heaters from the backside. Fabrication with resistive heaters for heterogeneous integration are compatible with the heterogeneous integration processes illustrated in FIGS. 1-14 and discussed above.

An example photonic device that uses these heterogeneous integration processes includes one or more resistive heaters, preferably fabricated using a material that is optically transparent (at the device operation wavelength and after heat treatment) and compatible with the CMOS fabrication process. Suitable heater materials include doped semiconductors, such as doped Si or Ge, since they can act as waveguide materials, are electrically conductive, and can withstand high temperatures. In particular, doped Si can act as both a heater and a waveguide to allow intimate integration of the deposited material with the Si PIC. Other suitable heater materials include silicides, transparent conducting oxides, graphene or other 2-D semi-metals, and metals.

Even though some of these heater materials are opaque, they can be transformed into transparent compounds after or during heat treatment. In these cases, the heaters can be considered single-use heaters. For instance, the initial resistive heater annealing process can be performed in an inert gas ambient atmosphere, followed by switching to an oxidative ambient atmosphere in which the resistive heaters become oxidized (e.g., oxidation turns them into transparent metal oxides).

The heater material can also act as a growth template for material that is deposited on the heater material and heat treated using the heater. As an example, single-crystalline Si or Ge heaters can be used to epitaxially seed the growth of large-grain Ge films upon annealing. Alternatively, the heater material can also be chosen to induce a preferred crystalline growth orientation, thereby producing a textured film after heat treatment. For example, polycrystalline PbTe grown on a glass substrate exhibits strong (200) texture.

Yet another option is to pattern the heaters (or the shape of the doped region) or use a micro-heater array to introduce a pre-defined temperature gradient to control the crystallization or grain growth direction. The temperature gradient can either be stationary or time-varying (by applying time-dependent voltage signals to the heater or heater array), for example, to perform a zone refining process. The capacity to introduce a preferred orientation via post-deposition on-chip heat treatment is useful in applications like increasing or maximizing the electro-optic activity of Pockels media.

The heaters should be placed away from on-chip components that are intolerant of high temperatures. If desired, deep etched trenches can partially surround the heater structure to reduce or minimize heat dissipation to other regions on the substrates.

The material to be integrated is deposited on or near the heaters at a temperature low enough to be compatible with the global thermal budget of the entire wafer. The functional material candidates that the integration method disclosed herein include but are not limited to electro-optic crystals (e.g., LiNbO₃ and BaTiO₃), magneto-optical crystals (various magneto-optical perovskites or garnets exemplified by cerium-substituted yttrium iron garnet Ce: YIG and bismuth-substituted yttrium iron garnet Bi:YIG), phase transition oxides or chalcogenides such as VO₂, and crystalline semiconductors such as Si, Ge, and compound semiconductors.

Materials deposited at low temperatures are often in an amorphous or a mixed amorphous/crystalline form, and therefore do not possess the desired optical or optoelectronic attributes for device applications. The low deposition temperature is commensurable with resist-based lift-off patterning, and films deposited on areas outside the desired heater regions can be removed via lift-off. A diffusion barrier layer may be added over the heater and other parts of the wafers to prevent unwanted contamination during the deposition and annealing processes. Similarly, a cap layer can be deposited on top of the material to encapsulate it. Other on-chip device structures can be subsequently built on top or around the heaters.

Local heat treatment of the deposited material is performed by passing electric current through the resistive heater(s). The electric current causes the heater(s) to reach temperatures well above the typical operating temperatures of on-chip heaters, for instance, around 1,000°. Because of the ‘single-use’ nature of the heaters, permanent changes or even damages to the heater structure that are normally unacceptable (e.g., dopant diffusion or electromigration) can be tolerated, provided that such damage does not cause significant increases in the PIC's optical losses or other deleterious effects. Properly designed heaters can deliver the high processing temperatures with little to no thermal cross-talk with other on-chip components.

FIG. 15 illustrates the cross section of a baseline photonic device 1500 and its fabrication process. The photonic device 1500 includes a doped silicon resistive heater 1504 on a buried oxide layer 1506, which in turn is on a silicon substrate 1508 (1). A thicker portion of the doped silicon resistive heater 1504 is in a trench etched into the photonic device 1500. The portions of the photonic device 1500 on both sides of the trench are formed of alternating layers of metal 1516, dielectric 1502 (e.g., silicon dioxide), and silicon nitride 1522, which may be formed into one or more waveguides. Electrical contacts 1514 run through these layers, connecting the metal layers 1516 to the doped silicon resistive heater 1504 and to bondpads 1518 on the frontside of the photonic device 1500. A passivation layer 1520 protects the photonic device's semiconductor layers.

Amorphous functional material 1510 is deposited in the trench on the exposed surface of the doped silicon resistive heater 1504 (2). In this example, the amorphous functional material 1510 is directly on the doped silicon resistive heater 1504, but there could be one or more intervening layers, provided that the amorphous functional material 1510 and the doped silicon resistive heater 1504 are thermally coupled well enough for the doped silicon resistive heater 1504 to heat the amorphous functional material 1510 to its transition temperature. If desired, the amorphous functional material 1510 can be coated or encapsulated with a protective encapsulation layer 1524 as shown in FIG. 15.

Once the amorphous functional material 1510 has been deposited, the contacts 1514 conduct current (e.g., from a current source (not shown) electrically coupled to the bondpads 1518) through the doped silicon resistive heater 1504. This causes the doped silicon resistive heater 1504 to heat the amorphous functional material 1510 to a temperature high enough that the amorphous functional material 1510 transitions to a crystalline state, becoming crystalline functional material 1512 (3). Because the doped silicon resistive heater 1504 is relatively small and also thermally isolated by the trench, it does not heat the rest of the wafer enough to cause permanent/noticeable damage.

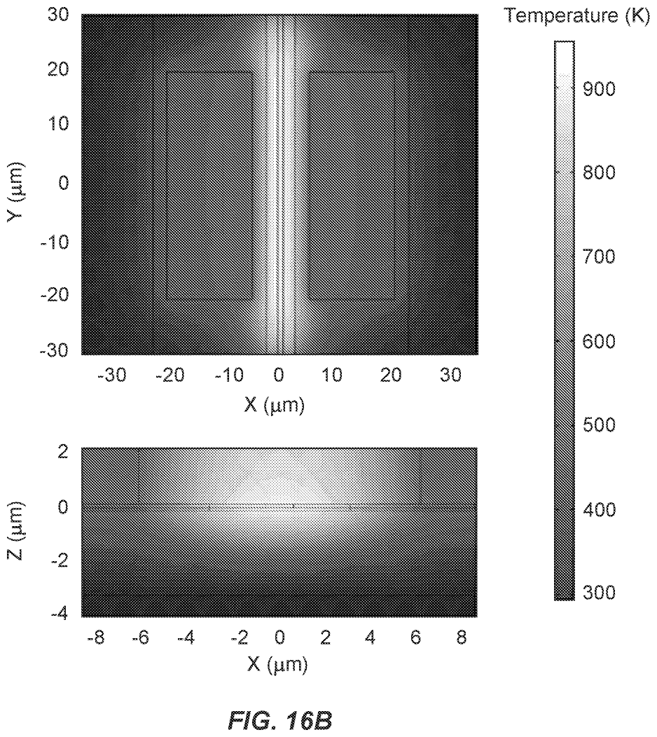

FIGS. 16A and 16B illustrate a photonic device 1600 with a 220-nm SOI waveguide-integrated heater 1602. FIG. 16A shows a cross section of the photonic device 1600, including the heater 1602, whose n-doped region also serves as a rib waveguide for guiding light. The heater 1602 is covered by a silicon dioxide cladding 1608 between a pair of n⁺⁺-doped Si regions 1604 on a buried silicon dioxide layer 1610. The n⁺⁺-doped Si regions 1604 are coupled to respective metal electrodes 1606.

FIG. 16B shows simulated top-view (top panel) and cross-sectional (bottom panel) temperature profiles when the heater is operating in a stationary state, showing good thermal confinement of the heating region. The stationary temperature distributions across the heater are simulated using the finite-element method. FIG. 16B indicates that the heating zones are tightly confined to around the waveguide core, and that heating becomes negligible at lateral distances of >30 μm away from the heater. This simulation indicates that local heat treatment is possible using resistive micro-heaters without disrupting the performance of other on-chip components.

Heterogeneous integration with resistive micro-heaters can be applied to non-photonic materials and devices as well. In that case, the optical properties of the heater or surrounding structures may be negligible, so the heater can be made of opaque materials. Examples include magnetic garnets (e.g., A₃Fe₅O₁₂ or A₃Fe₅₋ₓBₓO₁₂ where A=Y, rare earth, Bi, etc. and B is a substituent for Fe such as Ga, Al, Co etc.), other complex oxides (spinels, such as Fe₃O₄, CoFe₂O₄, Fe₂O₃, etc. or perovskites, such as ABO₃ where A=Sr, Ba, Y, rare earth, Bi, etc. and B is a transition metal) antiferromagnets (α-Fe₂O₃, NiO, etc.), ferroelectrics (BiFeO₃, lead zirconate titanate (PZT), lead magnesium niobate/lead titanate (PMN-PT), BaTiO₃ etc.), two phase magnetoelectric structures (BiFeO₃+CoFe₂O₄), superconductors (yttrium barium copper oxide YBCO), magnetically doped oxides (TiO₂/Co, etc.), paramagnets (TbGa garnet TGG). These have applications for spintronic devices such as racetrack memories where domain walls encode information, or for magnetic random-access memories where the magnetic state of a structure encodes information; for spin wave devices; for ferroelectric memories; and for multiferroic or magnetoelectric memory/logic devices. These are all ‘single use’ for the heater because the materials are stable once crystallized and the inventive method described herein can be adopted to significantly lower the global processing thermal budget of these materials.

To realize the baseline photonic structure 1500 depicted in FIG. 15, the PIC should be unclad or its cladding should be selectively etched to expose the PIC such that the deposited functional material can be close to the PIC's waveguide(s) and/or optoelectronics. Forming the functional material close to the waveguide(s) and/or optoelectronics increases the strength of the functional material's interactions with optical modes guided by the waveguide(s) and/or optoelectronics. This may involve modifying or adding steps to existing standard photonic foundry fabrication processes. It is also possible to integrate these functional materials without customizing or modifying industry standard foundry process flows as described below.

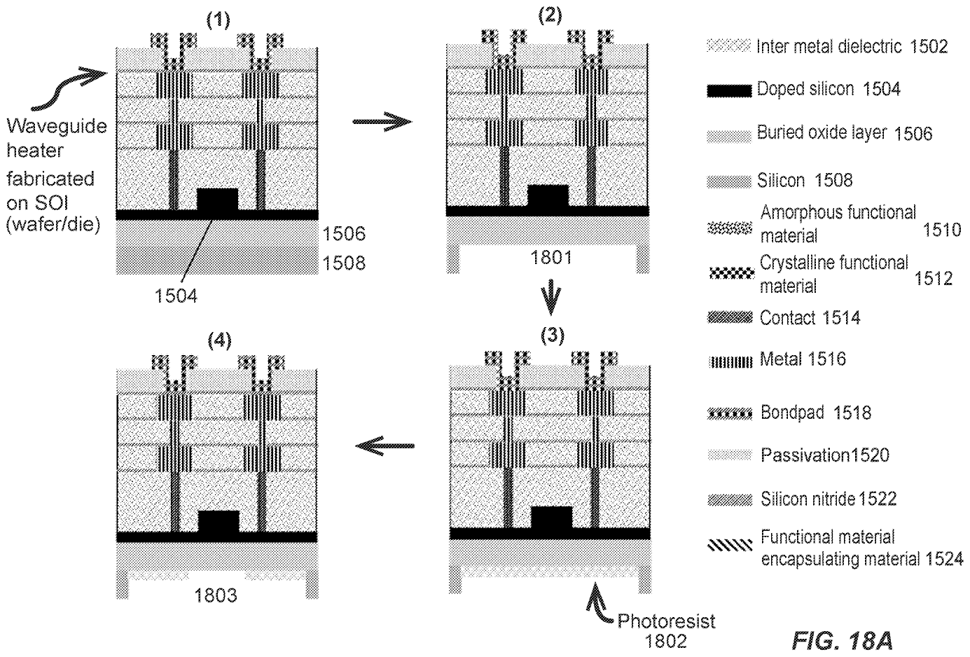

FIGS. 18A and 18B illustrate an embodiment of the integration process in the same layer stack shown in FIG. 15. The wafer/die is first processed at a foundry following standard protocols without any modifications (1). Through-wafer access holes 1801 are then etched into the silicon substrate 1508 (2). This can be accomplished via deep reactive ion etching (DRIE) of Si. When an SOI platform is used as in FIGS. 18A and 18B, the buried oxide layer 1506 serves as an etch stop. Lithographic patterning is carried out next to define the regions where the oxide under cladding will be removed: photoresist 1802 is deposited on the exposed surface of the buried oxide layer 1506 (3) and patterned (4) before a portion of the buried oxide layer 1506 is removed to expose the doped silicon resistive heater 1504. To account for the uneven backside surface, the photoresist 1802 can be deposited on the buried oxide layer 1506 using a resist spray coating process and the photoresist 1802 can be patterned using direct laser writing. The target amorphous functional material 1510 can be deposited into the regions where the oxide under cladding is etched (6) so that it can be in direct contact with the heater(s) 1504 in the PIC layer for subsequent heat treatment (7) with the heater(s) 1504. Heat treatment causes the amorphous functional material 1510 to crystallize, leaving crystalline functional material 1512 integrated with the under cladding.

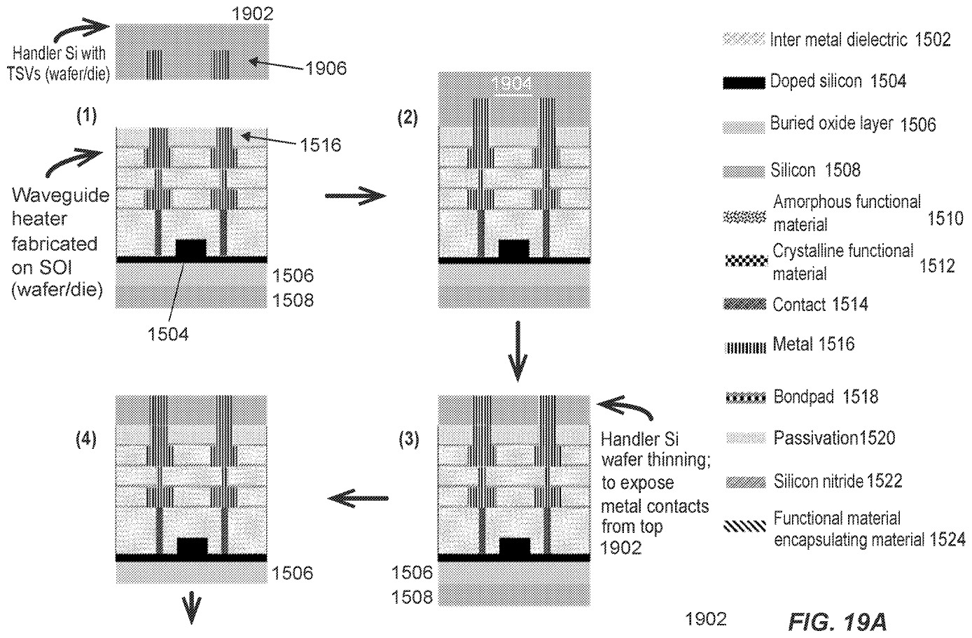

FIGS. 19A and 19B depict an alternative integration approach using the layer stack from FIG. 15 without bondpads on the frontside of the PIC wafer. The wafer/die is processed at a foundry following standard protocols before being bonded to a handler wafer 1902 (1). The handler wafer 1902 contains an array of through silicon vias (TSVs) 1906 designed to mate with the BEOL metal contacts 1516 on the frontside of the PIC wafer. During metal-to-metal direct wafer bonding (2), the TSVs 1906 are electrically connected to the BEOL metal contacts 1516. The handler substrate 1904 is then thinned to expose the TSV contacts 1906 on the unbonded side of the handler wafer 1902 to provide electrical I/O access (3). The handler wafer therefore serves as both a mechanical support and an electrical I/O interface.

The bulk Si substrate 1508 of the PIC wafer is then completely removed from the backside via chemical and/or mechanical methods (4), leaving a flat SiO₂ (buried oxide) surface. The SiO₂ 1506 can be either completely removed to expose the PIC layers (5) or lithographically patterned to open windows and provide physical access to the PIC. The doped silicon layer that forms the resistive heater 1504 can act as an etch stop (e.g., to a buffered oxide etch) in the process. Then amorphous functional material 1510 and an optional encapsulating layer 1524 are deposited on the exposed portion of the resistive heater 1504 (6), which heats the amorphous functional material 1510, transforming it into crystalline functional material 1512 (7).

If desired, an additional lithographic patterning step can be performed on the wafer back side to pattern the SOI layer. This allows structures to be engraved into both the front and back of the SOI layer, thereby enabling the creation of functional components that can be otherwise difficult to fabricate. One example is a corrugated grating coupler for extremely efficient optical I/O, which otherwise involves a complicated poly-Si overlay fabrication process not commonly available in foundries. Metasurface optical structures can also be defined in the Si layer underneath Ge-on-Si optoelectronic components to optimize light coupling into the Ge devices.

Additionally, unlike in an open-window approach, the layers above the SOI (e.g., Ge-on-Si, SiN waveguide layer, backend metals and interlayer dielectrics) are fully retained in this process. This unique feature enables a cohort of unconventional photonic device designs such as grating couplers with underlying metal or dielectric mirrors. Next, the material can be deposited on the PIC, (optionally) patterned, and heat treated as desired. After proper encapsulation of the material, the diced chips can then be mounted onto an interposer, a chip carrier, or another chip via a ball grid array or micro-bump array, e.g., as described above with respect to FIG. 1B.

Besides enabling post-deposition heat treatment, integrated resistive heaters also enable in situ thermal processing during material deposition. For thermal processing during material deposition, the heaters (without deposited materials) are loaded into the deposition or growth chamber and serve as the receiving substrate. During the deposition process, the heaters heat regions on the substrate to elevated temperatures. This approach allows specific material morphology or microstructure that are conventionally only accessible through deposition at high substrate temperatures, yet without subjecting the entire substrate to high heat. In this way, materials that normally must be deposited in the front-end-of-line (FEOL) process due to thermal budget constraints can also be grown after or during BEOL processing. It is also possible to vary the local substrate temperatures across a heater array to facilitate combinatorial evaluation of film growth conditions.

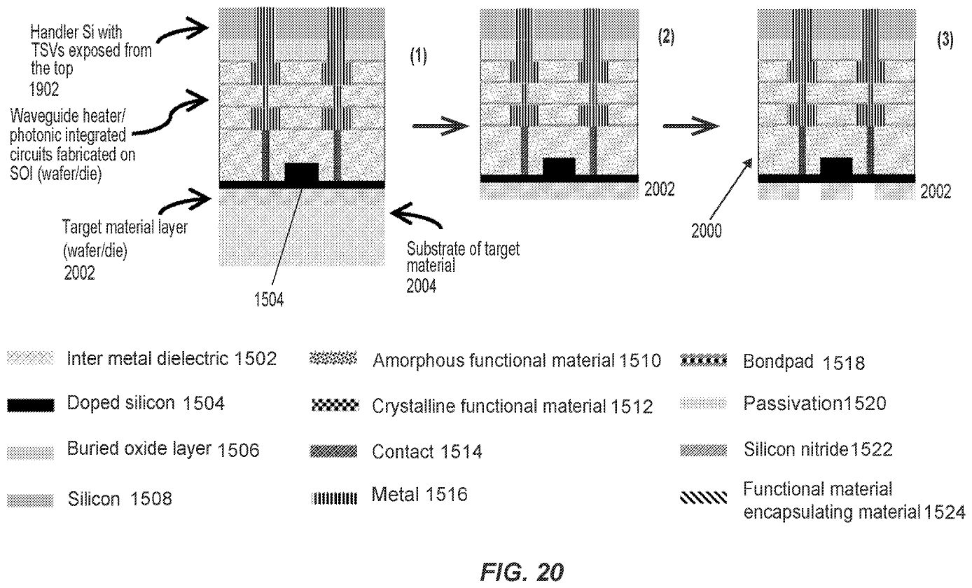

The backside integration method and structure described above and in FIG. 19 can also be applied to heterogeneous integration of materials using other techniques in addition to direct monolithic deposition. As illustrated in FIG. 20, small dies (or wafers) containing target material 2002 on a substrate 2004 can be bonded onto the exposed PIC devices, followed by bulk removal of the substrate 2004 (2) and patterning (3) of the target material layer 2002. Micro-transfer printing can similarly be adopted for transferring membranes of target materials onto the PIC devices. These methods apply to materials that may or may not require post-bonding/transfer heat treatment. The material candidates include single-crystalline compounds of aforementioned materials including electro-optic crystals, magneto-optical crystals, phase transition oxides or chalcogenides such as VO₂, compound semiconductors, and other complex oxides.

### CONCLUSION

While various inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize or be able to ascertain, using no more than routine experimentation, many equivalents to the specific inventive embodiments described herein. It is, therefore, to be understood that the foregoing embodiments are presented by way of example only and that, within the scope of the appended claims and equivalents thereto, inventive embodiments may be practiced otherwise than as specifically described and claimed. Inventive embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure.

Also, various inventive concepts may be embodied as one or more methods, of which an example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e., “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

1. (canceled)

2. (canceled)

3. (canceled)

4. (canceled)

5. (canceled)

6. (canceled)

7. (canceled)

8. (canceled)

9. (canceled)

10. (canceled)

11. (canceled)

12. (canceled)

13. (canceled)

14. (canceled)

15. (canceled)

16. (canceled)

17. (canceled)

18. (canceled)

19. (canceled)

20. (canceled)

21. (canceled)

22. (canceled)

23. (canceled)

24. (canceled)

25. (canceled)

26. (canceled)

27. A method of complementary metal-oxide-semiconductor (CMOS) integration, the method comprising:
selectively depositing a material in an amorphous state onto patterned resistive micro-heaters formed on a CMOS wafer at a temperature compatible with a global thermal budget of the CMOS wafer; and
passing electric current through the patterned resistive micro-heaters to locally heat the material, thereby causing the locally heated material to undergo at least one of controlled crystallization, grain growth, defect removal, or impurity rejection without exceeding the global thermal budget of the CMOS wafer.

28. (canceled)

29. (canceled)

30. The method of claim 27, further comprising, after passing the electric current through the patterned resistive micro-heaters, oxidizing the patterned resistive micro-heaters into transparent compounds.

31. The method of claim 27, wherein the patterned resistive micro-heaters are comprised of single-crystalline Si or Ge and wherein passing the electric current through the patterned resistive micro-heaters epitaxially seeds growth of large-grain Ge films.

32. The method of claim 27, wherein passing the electric current through the patterned resistive micro-heaters induces a preferred crystalline growth orientation in the material,

33. The method of claim 27, wherein passing the electric current through the patterned resistive micro-heaters causes the locally heated material to form an electrooptic crystal, magnetooptical crystal, phase transition oxide, phase transition oxide, phase change chalcogenide, crystalline semiconductor, or compound semiconductor.

34. (canceled)

35. (canceled)

36. (canceled)

37. (canceled)

38. (canceled)

39. (canceled)

40. (canceled)

41. (canceled)

42. The method of claim 27, wherein passing the electric current through the patterned resistive micro-heaters prevents the patterned resistive micro-heaters from being used to heat the material again.

43. A device for performing the method of claim 27, wherein the device comprises an array of the patterned resistive micro-heaters.

44. A CMOS device fabricated according to the method of claim 27.

45. The method of claim 27, further comprising applying time-dependent signals to the patterned resistive micro-heaters.

46. The method of claim 27, further comprising preventing heat dissipation from the patterned resistive micro-heaters to other regions of the CMOS wafer by providing a trench surrounding the patterned resistive micro-heaters.

47. The method of claim 27, further comprising depositing a cap layer on the material.

48. A complementary metal-oxide-semiconductor (CMOS) device comprising:
a CMOS substrate;
a patterned resistive micro-heater formed on the CMOS substrate; and
a crystalline material formed over the patterned resistive micro-heater.

49. The CMOS device of claim 48, wherein the patterned resistive micro-heater comprises doped Si or Ge.

50. The CMOS device of claim 48, wherein the patterned resistive micro-heater comprises at least one of a silicide, a transparent conducting oxide, a 2-D semi-metal, or a metal.

51. The CMOS device of claim 48, wherein the patterned resistive micro-heater is transparent at an operating wavelength of the CMOS device.

52. The CMOS device of claim 48, wherein the patterned resistive micro-heater is a single-use patterned resistive micro-heater.

53. The CMOS device of claim 48, wherein the patterned resistive micro-heater is formed of single-crystalline Si or Ge and the crystalline material comprises an annealed Ge film.

54. The CMOS device of claim 48, wherein the crystalline material comprises an electrooptic crystal, a magnetooptical crystal, a phase-transition oxide, a phase-change chalcogenide, a crystalline semiconductor, or a compound semiconductor.

55. The CMOS device of claim 48, wherein the crystalline material comprises a magnetic garnet selected from A₃Fe₅O₁₂, A₃Fe₅₋ₓBₓO₁₂, wherein A is selected from Y, rare earth, and Bi, and B is a Fe substituent selected from Ga, Al, and Co.

56. The CMOS device of claim 48, wherein the crystalline material comprises a complex oxide selected from spinels Fe₃O₄, CoFe₂O₄, and Fe₂O₃; a perovskite ABO₃ wherein A is selected from Sr, Ba, Y, rare earth, and Bi, and B is a transition metal; an antiferromagnets selected from α-Fe₂O₃ and NiO; a ferroelectric selected from BiFeO₃, lead zirconate titanate PZT, lead magnesium niobate/lead titanate PMN-PT, and BaTiO₃; a two phase magnetoelectric structure selected from BiFeO₃ and CoFe₂O₄; a superconductor comprised of yttrium barium copper oxide YBCO; a magnetically-doped oxide comprised of TiO₂/Co; or a paramagnet comprised of TbGa garnet TGG.
